(19) United States
(12) Patent Application Publication
(10) Pub. No.: US 2023/0109153 A1
(43) Pub. Date: Apr. 6, 2023

(54) CURABLE COMPOSITION FOR IMPRINTING, COATING FILM, METHOD FOR PRODUCING FILM, CURED PRODUCT, METHOD FOR PRODUCING IMPRINT PATTERN, AND METHOD FOR PRODUCING DEVICE

(71) Applicant: FUJIFILM Corporation, Tokyo (JP)

(72) Inventors: Akihiro Hakamata, Haibara-gun (JP); Naoya Shimoju, Haibara-gun (JP)

(73) Assignee: FUJIFILM Corporation, Tokyo (JP)

(21) Appl. No.: 17/895,498

(22) Filed: Aug. 25, 2022

(30) Foreign Application Priority Data
Aug. 27, 2021 (JP) 2021-138513

(51) Int. Cl. G03F 7/00; G03F 7/075; G03F 7/34

(52) U.S. Cl. CPC G03F 7/0002; G03F 7/0037; G03F 7/0757; G03F 7/346

(57) ABSTRACT

There are provided a curable composition for imprinting, the curable composition including an organopolysiloxane having a radical polymerizable group, a radical generator, and a compound that has a monovalent hydrocarbon group having 4 to 11 carbon atoms and a poly(oxyalkylene) group, in which some or all of hydrogen atoms of the monovalent hydrocarbon group are optionally substituted with halogen atoms, a coating film of the composition, a method for producing the film, a cured product of the composition, a method for producing an imprint pattern using the composition, and a method for producing a device, the method including the method for producing an imprint pattern.

### CROSS-REFERENCE TO RELATED APPLICATIONS

The present application claims priority under 35 U.S.C § 119 to Japanese Patent Application No. 2021-138513 filed on Aug. 27, 2021. Each of the above application(s) is hereby expressly incorporated by reference, in its entirety, into the present application.

### BACKGROUND OF THE INVENTION

### 1. Field of the Invention

The present invention relates to a curable composition for imprinting and to a coating film, a method for producing a film, a cured product, a method for producing an imprint pattern, and a method for producing a device, using the curable composition for imprinting.

### 2. Description of the Related Art

An imprint method is a technique of transferring a fine pattern to a material by pressing a die (generally called a mold or a stamper) on which a pattern is formed. Since precise fine patterns can be easily made by the imprint method, in recent years, the imprint method is expected to be applied to various fields. In particular, a nanoimprint technique for forming fine patterns on the order of nanometers has attracted attention.

WO2017/195586A discloses a curable composition for photoimprinting, the curable composition including a polymerizable compound (A) containing a silicon atom in the molecule, a photopolymerization initiator (B), and an additive (C), in which the additive (C) is a compound having a specific structure.

WO2019/188882A discloses a curable composition for imprinting, the curable composition including a monofunctional polymerizable compound having a specific structure, a photopolymerization initiator, and a mold release agent having a specific structure.

### SUMMARY OF THE INVENTION

As the imprint method, methods called a thermal imprint method and a curing imprint method have been proposed in view of the transfer method thereof. In the thermal imprint method, a mold is pressed against a thermoplastic resin heated to a glass transition temperature (hereinafter, also referred to as “Tg”) or higher, and the mold is released after cooling to form a fine pattern. In this method, various materials can be selected; however, this method also has a problem in that it is difficult to form a fine pattern because, for example, a high pressure is required during pressing, and the dimensional accuracy decreases due to thermal shrinkage or the like.

On the other hand, in the curing imprint method, for example, while a mold is pressed against a film formed from a curable composition for imprinting, the film is cured by light or heat, and the mold is then released. Since imprinting is performed on an uncured product, a part or all of high-pressure application and high-temperature heating can be omitted, and a fine pattern can be easily made. In addition, since the dimensional change before and after curing is small, the curing imprint method is advantageous in that a fine pattern can be formed with high accuracy.

Recently, new developments such as a nanocasting method that combines the advantages of both the thermal imprint method and the curing imprint method, and a reversal imprint method for making a three-dimensional laminated structure have also been reported.

In the curing imprint method, a curable composition for imprinting is applied onto a support (whose surface is subjected to an adhesion treatment as necessary) to form a film, and a mold made of a light-transmitting material such as quartz is then pressed against the film. The curable composition for imprinting is cured by light irradiation or heating in a state in which the mold is pressed against the film, and the mold is then released to produce a cured product to which a target pattern has been transferred.

Examples of the method for applying the curable composition for imprinting onto the support include a spin coating method and an inkjet method. The spin coating method is an application method excellent in productivity in terms of high throughput.

A method of performing microfabrication using a transferred imprint pattern as a mask is referred to as nanoimprint lithography (NIL) and is being developed as a next-generation lithography technique that replaces the existing ArF immersion process. Therefore, the curable composition for imprinting used in NIL is required to be capable of resolving an ultrafine pattern of 20 nm or less and to have high etching resistance as a mask for microfabrication of an object to be processed, similarly to an extreme ultraviolet (EUV) resist. Specific examples of curable compositions for imprinting intended to be used as a mask include those described in JP5426814B, JP2015-009171A, JP2015-185798A, JP2015-070145A, and JP2015-128134A.

In the imprint method, for the purpose of, for example, suppressing deformation and breakage of a cured product and damage of a mold, a force (mold release force) required to peel a mold and a cured product of a curable composition for imprinting from each other is required to be small.

An object of the present invention is to provide a curable composition for imprinting, the curable composition providing a cured product having a small mold release force between the cured product and a mold, a coating film of the curable composition for imprinting, a method for producing the film, a cured product of the curable composition for imprinting, a method for producing an imprint pattern using the curable composition for imprinting, and a method for producing a device, the method including the method for producing an imprint pattern.

Representative embodiments of the present invention will be described below.
<1>A curable composition for imprinting, including:
   an organopolysiloxane having a radical polymerizable group;
   a radical generator; and
   a compound that has a monovalent hydrocarbon group having 4 to 11 carbon atoms and a poly(oxyalkylene) group,
   wherein some or all of hydrogen atoms of the monovalent hydrocarbon group are optionally substituted with halogen atoms.
<2> The curable composition for imprinting according to <1>, wherein the number of repetitions of an oxyalkylene group in the poly(oxyalkylene) group is 4 to 20.
<3> The curable composition for imprinting according to <1> or <2>, wherein an oxyalkylene group in the poly(oxyalkylene) group has 2 or 3 carbon atoms.
<4> The curable composition for imprinting according to any one of <1> to <3>, wherein the monovalent hydrocarbon group is a linear alkyl group or a branched alkyl group.
<5> The curable composition for imprinting according to any one of <1> to <4>, wherein the compound has two monovalent hydrocarbon groups, each of which is the aforementioned monovalent hydrocarbon group.
<6> The curable composition for imprinting according to any one of <1> to <5>, wherein the monovalent hydrocarbon group is directly bonded to the poly(oxyalkylene) group.
<7> The curable composition for imprinting according to any one of <1> to <6>, wherein the monovalent hydrocarbon group is an unsubstituted hydrocarbon group.
<8> The curable composition for imprinting according to any one of <1> to <7>, wherein a content of the poly(oxyalkylene) group in the compound is 30% to 90% by mass.
<9> The curable composition for imprinting according to any one of <1> to <8>, wherein the compound is a compound represented by formula (C-1) below.

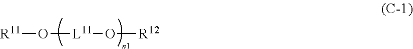

In formula (C-1), R¹¹ and R¹² each independently represent a hydrogen atom or a monovalent organic group, at least one of R¹¹ or R¹² is a monovalent hydrocarbon group having 4 to 11 carbon atoms, each L^{H} independently represents an alkylene group, and n1 represents an integer of 2 or more.
<10>A curable composition for imprinting, including:
   an organopolysiloxane having a radical polymerizable group;
   a radical generator; and
   a compound represented by formula (C-2) below.

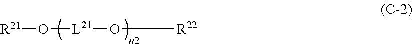

In formula (C-2), R²¹ and R²² each independently represent a monovalent hydrocarbon group, each L²′ independently represents an alkylene group, and n2 represents an integer of 2 or more.
<11> The curable composition for imprinting according to any one of <1> to <10>, wherein the compound has a weight-average molecular weight of 300 to 1,000.
<12> The curable composition for imprinting according to any one of <1> to <11>, wherein a content of the compound is 0.5% to 10% by mass relative to a total solid content of the composition.
<13> The curable composition for imprinting according to any one of <1> to <12>, wherein the compound has no radical polymerizable group.
<14> The curable composition for imprinting according to any one of <1> to <13>, wherein a content of the compound relative to a total mass of the organopolysiloxane is 0.5% to 10% by mass.
<15> The curable composition for imprinting according to any one of <1> to <14>, wherein a content of a solvent relative to a total mass of the composition is 90% to 99% by mass.
<16>A coating film including the curable composition for imprinting according to any one of <1> to <15>.
<17>A method for producing a film, the method including a step of applying the curable composition for imprinting according to any one of <1> to <15>onto a support or a mold.
<18>A cured product obtained by curing the curable composition for imprinting according to any one of <1> to <15>.
<19>A method for producing an imprint pattern, the method including:
   an application step of applying the curable composition for imprinting according to any one of <1> to <15> to a member to be coated selected from the group consisting of a support and a mold;
   a contact step of bringing, as a contact member, a member which is not selected as the member to be coated in the group consisting of the support and the mold into contact with the curable composition for imprinting;
   a curing step of curing the curable composition for imprinting to form a cured product; and
   a peeling step of peeling the mold and the cured product from each other.
<20> The method for producing an imprint pattern according to <19>, wherein the support is a member including an adhesive layer on a surface to which the curable composition for imprinting is to be applied.
<21>A method for producing a device, the method including the method for producing an imprint pattern according to <19> or <20>.

According to the present invention, there are provided a curable composition for imprinting, the curable composition providing a cured product having a small mold release force between the cured product and a mold, a coating film of the curable composition for imprinting, a method for producing the film, a cured product of the curable composition for imprinting, a method for producing an imprint pattern using the curable composition for imprinting, and a method for producing a device, the method including the method for producing an imprint pattern.

### DESCRIPTION OF THE PREFERRED EMBODIMENTS

Hereafter, features of the present invention will be described in detail.

In the present specification, “to” is used to mean a range that includes a numerical value before “to” as a lower limit and a numerical value after “to” as an upper limit.

In the present specification, the term “(meth)acrylate” represents acrylate and methacrylate, the term “(meth)acryl” represents acryl and methacryl, and the term “(meth)acryloyl” represents acryloyl and methacryloyl. The term “(meth)acryloyloxy” represents acryloyloxy and methacryloyloxy.

In the present specification, the term “imprinting” preferably refers to a transfer of a pattern with a size of 1 nm to 10 mm and more preferably refers to a transfer of a pattern with a size of about 10 nm to 100 μm (nanoimprinting).

In the expression of groups (atomic groups) in the present specification, an expression without the term of substituted or unsubstituted encompasses groups having no substituents and also groups having substituents. For example, the term “alkyl group” encompasses not only an alkyl group having no substituents (unsubstituted alkyl group) but also alkyl groups having substituents (substituted alkyl groups).

In the present specification, the term “light” encompasses not only light having a wavelength in a region of ultraviolet, near-ultraviolet, far-ultraviolet, visible, infrared, or the like and electromagnetic waves, but also radiation. Examples of the radiation include microwaves, electron beams, extreme ultraviolet radiation (EUV), and X-rays. Laser beams such as 248 nm excimer laser, 193 nm excimer laser, and 172 nm excimer laser can also be used. The light may be monochromatic light (single-wavelength light) that has passed through an optical filter or may be light having a plurality of different wavelengths (compound light).

In the present specification, the weight-average molecular weight (Mw) and the number-average molecular weight (Mn) are defined as values in terms of polystyrene according to gel permeation chromatography (GPC measurement) unless otherwise specified. In the present specification, the weight-average molecular weight (Mw) and the number-average molecular weight (Mn) can be determined with, for example, HLC-8220 (manufactured by Tosoh Corporation) using, as columns, a guard column HZ-L, TSKgel Super HZM-M, TSKgel Super HZ4000, TSKgel Super HZ3000, or TSKgel Super HZ2000 (manufactured by Tosoh Corporation). THF (tetrahydrofuran) is used as an eluant for the measurement unless otherwise specified. Unless otherwise specified, a detector at a wavelength of 254 nm of UV rays (ultraviolet rays) is used for the detection.

In the present specification, unless otherwise specified, the temperature is 23° C., the atmospheric pressure is 101,325 Pa (1 atm), and the relative humidity is 50% RH.

In the present specification, the term “step” refers to not only an independent step but also a step that is not clearly distinguished from another step as long as a desired operation of the step is achieved.

In the present specification, the term “total solid content” refers to the total mass of components excluding a solvent from all components of the composition. In the present specification, the term “concentration of solid contents” refers to a mass percentage of components other than the solvent relative to the total mass of the composition.

In the present specification, combinations of preferred embodiments are more preferred embodiments.

A curable composition for imprinting according to a first embodiment of the present invention includes an organopolysiloxane having a radical polymerizable group, a radical generator, and a compound that has a monovalent hydrocarbon group having 4 to 11 carbon atoms and a poly(oxyalkylene) group, in which some or all of hydrogen atoms of the monovalent hydrocarbon group are optionally substituted with halogen atoms.

A curable composition for imprinting according to a second embodiment of the present invention includes an organopolysiloxane having a radical polymerizable group, a radical generator, and a compound represented by the following formula (C-2).

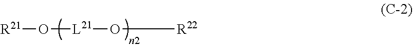

In formula (C-2), R²¹ and R²² each independently represent a monovalent hydrocarbon group, each L²′ independently represents an alkylene group, and n2 represents an integer of 2 or more.

Hereinafter, the simple description “composition according to the present invention” or “curable composition for imprinting according to the present invention” refers to both the curable composition for imprinting according to the first embodiment of the present invention and the curable composition for imprinting according to the second embodiment of the present invention.

The compound that has a monovalent hydrocarbon group having 4 to 11 carbon atoms and a poly(oxyalkylene) group in the curable composition for imprinting according to the first embodiment is also referred to as a “specific compound 1”.

Furthermore, the compound represented by formula (C-2) in the curable composition for imprinting according to the second embodiment is also referred to as a “specific compound 2”.

Hereinafter, the simple description “specific compound” refers to both the specific compound 1 and the specific compound 2.

According to the curable composition for imprinting according to the present invention, a mold release force between an obtained cured product and a mold is small.

The mechanism of this effect is not known but is presumed as follows.

The curable composition for imprinting according to the first embodiment of the present invention includes the specific compound 1.

The curable composition for imprinting according to the second embodiment of the present invention includes the specific compound 2.

Here, since the poly(oxyalkylene) group contained in the specific compound 1 or the specific compound 2 is likely to adsorb to the mold, the specific compound is unevenly distributed on the surface of an imprint pattern after curing. In particular, since the specific compound 1 has a monovalent hydrocarbon group having 4 to 11 carbon atoms, and the specific compound 2 has two monovalent hydrocarbon groups, a mold release agent is probably easily segregated on a template surface in terms of compatibility with the organopolysiloxane having a radical polymerizable group.

As a result, the monovalent hydrocarbon group having 4 to 11 carbon atoms in the specific compound 1 is unevenly distributed near the surface of the imprint pattern, or the monovalent hydrocarbon groups which are R²¹ and R²² in the specific compound 2 are also unevenly distributed on the surface of the imprint pattern. Probably, as a result, for example, the surface free energy of the imprint pattern is lowered; and therefore, the force required to release the mold and the imprint pattern from each other can be lowered to reduce the mold release force. When the number of carbon atoms is 11 or more, the compositional ratio of hydrocarbon increases, so that the pattern becomes soft, and pattern collapse or coming off is likely to occur.

In addition, since the specific compound 1 or the specific compound 2 is included, the compositional ratio of hydrocarbon increases, and thus cleaning properties in sulfuric acid-hydrogen peroxide mixture (SPM) cleaning are considered to be improved.

Hereafter, the present invention will be described in detail.

Organopolysiloxane Having Radical Polymerizable Group

A curable composition for imprinting according to the present invention includes an organopolysiloxane having a radical polymerizable group.

### Radical Polymerizable Group

The radical polymerizable group in the organopolysiloxane having a radical polymerizable group is preferably an ethylenically unsaturated bond-containing group, and examples thereof include a (meth)acryloyl group, a (meth)acryloxy group, a (meth)acrylamide group, a vinyl group, a vinyloxy group, an allyl group, a maleimide group, and a group in which a vinyl group is directly bonded to an aromatic ring (for example, a vinylphenyl group). A (meth)acrylamide group or a (meth)acryloxy group is more preferred, an acrylamide group or an acryloxy group is still more preferred, and an acryloxy group is particularly preferred. Organopolysiloxane

The organopolysiloxane refers to a compound containing siloxane bonds (—Si—O—Si—O—Si—) as a skeleton and having an organic group bonded to a silicon atom thereof

In the organic group, the atom bonded to the silicon atom is preferably a carbon atom.

An atom or group other than an organic group (for example, a hydrogen atom, a hydroxy group, or a hydrolyzable group) may be bonded to some of the silicon atoms.

The hydrolyzable group is a group that can react with water to form a hydroxy group, and examples thereof include a halogen atom (such as a chlorine atom), an alkoxy group, an acyl group, and an amino group.

The organic group is preferably a hydrocarbon group, and more preferably an aromatic hydrocarbon group or a saturated aliphatic hydrocarbon group. The hydrocarbon group, the aromatic hydrocarbon group, and the saturated aliphatic hydrocarbon group may each further have a substituent. Examples of the substituent include a halogen atom, an alkoxy group, an aryloxy group, and a group including the radical polymerizable group mentioned above.

The organopolysiloxane having a radical polymerizable group is preferably a compound having at least one of a siloxane structure of the D unit represented by the following formula (Si) or a siloxane structure of the T unit represented by the following formula (S2).

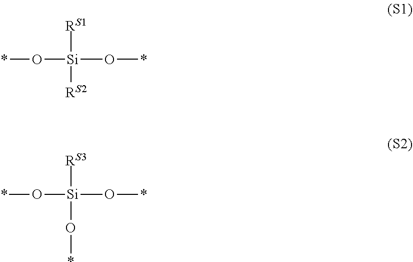

In formula (S1) or formula (S2), R^{si} to R^{S3} each independently represent a hydrogen atom or a monovalent substituent, and each * independently represents a bonding site to another structure.

R^{s1} to R^{S3} are each independently preferably a monovalent substituent.

The monovalent substituent is preferably an aromatic hydrocarbon group (preferably having 6 to 22 carbon atoms, more preferably 6 to 18 carbon atoms, and still more preferably 6 to 10 carbon atoms) or an aliphatic hydrocarbon group (preferably having 1 to 24 carbon atoms, more preferably 1 to 12 carbon atoms, and still more preferably 1 to 6 carbon atoms). Of these, a cyclic or chain-like (linear or branched) alkyl group (preferably having 1 to 12 carbon atoms, more preferably 1 to 6 carbon atoms, and still more preferably 1 to 3 carbon atoms) or a group including a polymerizable group is preferred.

Specific examples of the structure of the organopolysiloxane include partial structures represented by the following formulae (s-1) to (s-9). Q in the formulae is the group including a radical polymerizable group. A plurality of these structures may be present in the compound or may be present in combination.

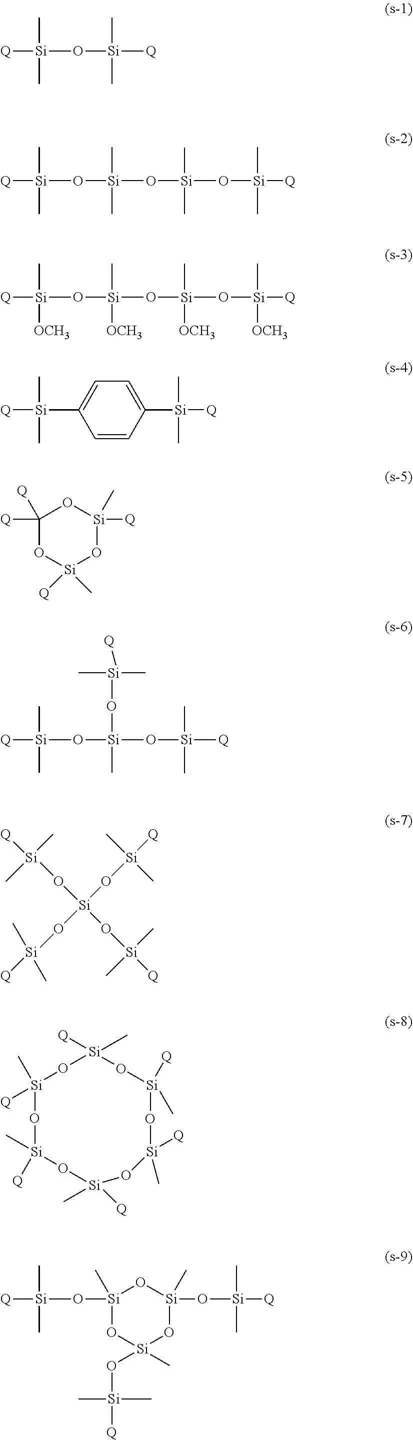

The organopolysiloxane having a radical polymerizable group is preferably a reaction product of a silicone resin and a compound having a polymerizable group.

The silicone resin is preferably a reactive silicone resin.

Examples of the reactive silicone resin include modified silicone resins having the silicone skeleton described above, such as monoamine-modified silicone resins, diamine-modified silicone resins, special amino-modified silicone resins, epoxy-modified silicone resins, alicyclic-epoxy-modified silicone resins, carbinol-modified silicone resins, mercapto-modified silicone resins, carboxy-modified silicone resins, hydrogen-modified silicone resins, amino/polyether-modified silicone resins, epoxy/polyether-modified silicone resins, and epoxy/aralkyl-modified silicone resins.

The compound having a polymerizable group is preferably a compound having a polymerizable group and a group that can react with an alkoxysilyl group or a silanol group, and more preferably a compound having a polymerizable group and a hydroxy group.

When the modified silicone resin described above is used as the silicone resin, a compound having a polymerizable group and a group that reacts with an amino group, an epoxy group, a mercapto group, a carboxy group, or the like included in the modified silicone resin may be used as the compound having a polymerizable group.

Preferred embodiments of the polymerizable group in the compound having a polymerizable group are the same as the preferred embodiments of the polymerizable group in the polymerizable compound described above.

Of these, as the compound having a polymerizable group, a hydroxyalkyl (meth)acrylate is preferred, and 2-hydroxyethyl (meth)acrylate is more preferred.

More specifically, the organopolysiloxane is preferably a reaction product of a compound having a polymerizable group and a group (for example, a hydroxy group) that can react with an alkoxysilyl group or a silanol group and a silicone resin having an alkoxysilyl group or a silanol group.

The weight-average molecular weight of the organopolysiloxane having a radical polymerizable group is preferably 500 to 10,000, more preferably 800 to 5,000, and still more preferably 1,000 to 3,000.

The number of radical polymerizable groups in the organopolysiloxane having a radical polymerizable group is preferably two or more, more preferably three or more, and still more preferably four or more in one molecule. The upper limit is preferably 50 or less, more preferably 40 or less, still more preferably 30 or less, and even more preferably 20 or less.

The organopolysiloxane having a radical polymerizable group preferably has a viscosity of 100 mPa·s or more, more preferably 120 mPa·s or more, and still more preferably 150 mPas or more, at 23° C. The upper limit of the viscosity is preferably 2,000 mPas or less, more preferably 1,500 mPas or less, and still more preferably 1,200 mPas or less.

In the present specification, unless otherwise specified, the viscosity is a value measured using an E-type rotational viscometer RE85L manufactured by Toki Sangyo Co., Ltd. and a standard cone rotor (1° 34′ 8 R24) while the temperature of a sample cup is adjusted to 23° C. Other details regarding the measurement are based on JISZ8803:2011. Two samples are prepared for one level, and each sample is measured three times. The arithmetic mean value of the total of six measurements is adopted as the evaluation value.

### Other Polymerizable Compound

The curable composition for imprinting according to the present invention may further include another polymerizable compound different from the above-described organopolysiloxane having a radical polymerizable group.

The other polymerizable compound is preferably a polyfunctional polymerizable compound having two or more polymerizable groups. The number of polymerizable groups of the other polymerizable compound is preferably two or more in one molecule. The upper limit is preferably 4 or less, more preferably 3 or less, and still more preferably 2 or less.

Examples of the polymerizable group in the other polymerizable compound include, but are not particularly limited to, radical polymerizable groups and cyclic ether groups (such as an epoxy group, a glycidyl group, and an oxetanyl group), and radical polymerizable groups are preferred. The polymerizable group defined here is referred to as Qp.

Preferred embodiments of the radical polymerizable group in the other polymerizable compound are the same as the preferred embodiments of the radical polymerizable group in the above-described organopolysiloxane having a radical polymerizable group.

Examples of the other polymerizable compound include compounds represented by the following formula.

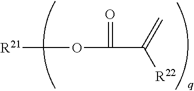

In the formula, R²¹ is a q-valent organic group, R²² is a hydrogen atom or a methyl group, and q is an integer of 2 or more. q is preferably an integer of 2 or more and 7 or less, more preferably an integer of 2 or more and 4 or less, still more preferably 2 or 3, and even more preferably 2.

R²¹ is preferably a divalent to heptavalent organic group, more preferably a divalent to tetravalent organic group, still more preferably a divalent or trivalent organic group, and even more preferably a divalent organic group. R²¹ is preferably a hydrocarbon group having at least one of a linear, branched, or ring structure. The number of carbon atoms of the hydrocarbon group is preferably 2 to 20, and more preferably 2 to 10.

When R²¹ is a divalent organic group, R²¹ is preferably an organic group represented by the following formula (1-2).

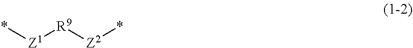

In the formula, Z¹ and Z² are each independently preferably a single bond, —Alk—, or -Alk—O— (where Alk and 0 may be in any order and may be —O—Alk— in the formula). Alk represents an alkylene group (preferably having 1 to 12 carbon atoms, more preferably 1 to 6 carbon atoms, and still more preferably 1 to 3 carbon atoms) and may have a substituent as long as the effect of the present invention is not impaired.

R⁹ is preferably a single bond, a linking group selected from the group consisting of the following formulae (9-1) to (9-10), or a combination thereof Of these, a linking group selected from the group consisting of formulae (9-1) to (9-3), (9-7), and (9-8) is preferred.

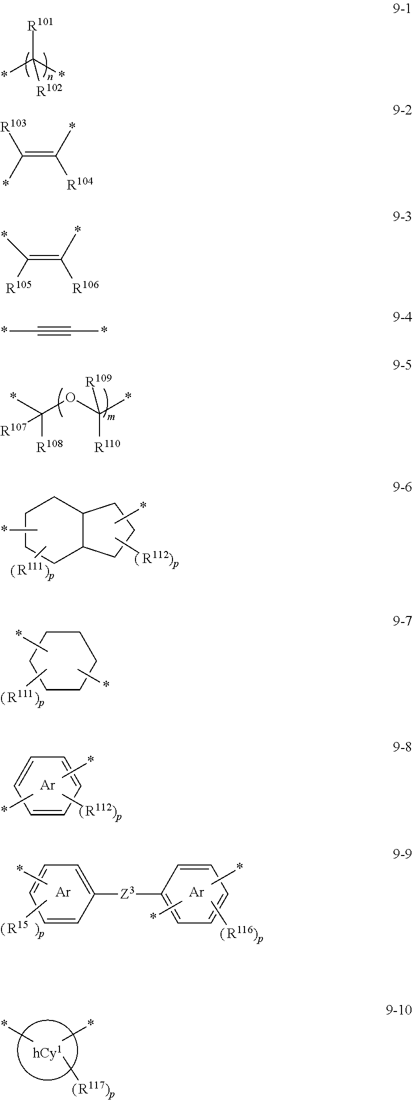

R¹⁰¹ to R¹¹⁷ are each any substituent. In particular, an alkyl group (preferably having 1 to 12 carbon atoms, more preferably 1 to 6 carbon atoms, and still more preferably 1 to 3 carbon atoms), an aralkyl group (preferably having 7 to 21 carbon atoms, more preferably 7 to 15 carbon atoms, and still more preferably 7 to 11 carbon atoms), an aryl group (preferably having 6 to 22 carbon atoms, more preferably 6 to 18 carbon atoms, and still more preferably 6 to 10 carbon atoms), a thienyl group, a furyl group, a (meth)acryloyl group, a (meth)acryloyloxy group, and a (meth)acryloyloxyalkyl group (where the alkyl group preferably has 1 to 24 carbon atoms, more preferably 1 to 12 carbon atoms, and still more preferably 1 to 6 carbon atoms) are preferred. R¹⁰¹ and R¹⁰², R¹⁰³ and R¹⁰⁴ , R¹⁰⁵ and R¹⁰⁶, R¹⁰⁷ and R¹⁰⁸, R¹⁰⁹ and R¹¹⁰a plurality of R¹¹¹, if present, a plurality of R¹¹², if present, a plurality of R¹¹³, if present, a plurality of R¹¹⁴, if present, a plurality of R¹¹⁵, if present, a plurality of R¹¹⁶, if present, and a plurality of R¹¹⁷, if present may be bonded together to form a ring.

Ar is an arylene group (preferably having 6 to 22 carbon atoms, more preferably 6 to 18 carbon atoms, and still more preferably 6 to 10 carbon atoms), and specific examples thereof include a phenylene group, a naphthalenediyl group, an anthracenediyl group, a phenanthrenediyl group, and a fluorenediyl group.

hCy¹ is a heterocyclic group (preferably having 1 to 12 carbon atoms, more preferably 1 to 6 carbon atoms, and still more preferably 2 to 5 carbon atoms), and more preferably a five-membered ring or a six-membered ring. Specific examples of the heterocycle constituting hCy¹ include aromatic heterocycles hCy described below, a pyrrolidone ring, a tetrahydrofuran ring, a tetrahydropyran ring, and a morpholine ring. Of these, a thiophene ring, a furan ring, and a dibenzofuran ring are preferred.

n and m are each a natural number of 100 or less, preferably 1 to 12, more preferably 1 to 6, and still more preferably 1 to 3.

p is an integer greater than or equal to 0 and less than or equal to the maximum substitutable number for each ring. The upper limit is, independently in each case, preferably a half or less of the maximum substitutable number, more preferably 4 or less, and still more preferably 2 or less.

In the present specification, the radical polymerizable group value of a compound is calculated by the following formula. (Radical polymerizable group value)=(Number-average molecular weight of compound)/(Number of polymerizable groups in compound)

The other polymerizable compound preferably has a radical polymerizable group value of 150 or more, more preferably 160 or more, still more preferably 190 or more, and even more preferably 240 or more, the polymerizable group value being defined above. The upper limit is preferably 2,500 or less, more preferably 1,800 or less, and still more preferably 1,000 or less.

The other polymerizable compound preferably has a ring structure. Examples of the ring structure include examples of an aromatic hydrocarbon ring aCy, an aromatic heterocycle hCy, and an alicyclic ring fCy described below.

Examples of the other polymerizable compound include compounds including a ring structure (ring-containing compounds) and dendrimer-type compounds.

### Ring-Containing Compound

Examples of the ring structure of the compound including a ring (ring-containing compound) include an aromatic ring and an alicyclic ring. Examples of the aromatic ring include an aromatic hydrocarbon ring and an aromatic heterocycle.

The aromatic hydrocarbon ring preferably has 6 to 22 carbon atoms, more preferably 6 to 18 carbon atoms, and still more preferably 6 to 10 carbon atoms. Specific examples of the aromatic hydrocarbon ring include a benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring. Of these, a benzene ring or a naphthalene ring is preferred, and a benzene ring is more preferred. The aromatic ring may have a structure in which a plurality of aromatic rings are linked together, and examples thereof include a biphenyl structure and a diphenylalkane structure (for example, 2,2-diphenylpropane). (The aromatic hydrocarbon ring specified here is referred to as aCy.)

The aromatic heterocycle preferably has 1 to 12 carbon atoms, more preferably 1 to 6 carbon atoms, and still more preferably 1 to 5 carbon atoms. Specific examples thereof include a thiophene ring, a furan ring, a dibenzofuran ring, a pyrrole ring, an imidazole ring, a benzimidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, a pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiin ring, and a phenoxazine ring. (The aromatic heterocycle specified here is referred to as hCy.)

The alicyclic ring preferably has 3 to 22 carbon atoms, more preferably 4 to 18 carbon atoms, and still more preferably 6 to 10 carbon atoms. Specific examples of the aliphatic hydrocarbon ring include a cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydrodicyclopentadiene ring, an octahydronaphthalene ring, a decahydronaphthalene ring, a hexahydroindane ring, a bornane ring, a norbornane ring, a norbornene ring, isobornane ring, a tricyclodecane ring, a tetracyclododecane ring, and an adamantane ring. Examples of the aliphatic heterocycle include a pyrrolidine ring, an imidazolidine ring, a piperidine ring, a piperazine ring, a morpholine ring, an oxirane ring, an oxetane ring, an oxolane ring, an oxane ring, and a dioxane ring. (The alicyclic ring specified here is referred to as fCy.)

In the present invention, when the other polymerizable compound is a ring-containing compound, the ring-containing compound is preferably a compound including an aromatic hydrocarbon ring, and more preferably a compound having a benzene ring. The compound may be, for example, a compound having a structure represented by the following formula (C-1).

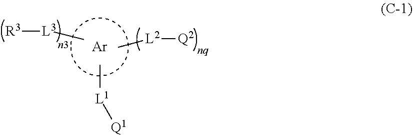

In the formula, Ar represents the aromatic hydrocarbon ring or aromatic heterocycle described above.

L¹ and L² each independently represent a single bond or a linking group. Examples of the linking group include an oxygen atom (oxy group), a carbonyl group, an imino group, an alkylene group (preferably having 1 to 12 carbon atoms, more preferably 1 to 6 carbon atoms, and still more preferably having 1 to 3 carbon atoms), and a group of a combination of the foregoing. Of these, a (poly)alkyleneoxy group is preferred. The (poly)alkyleneoxy group may be a group formed of a single alkyleneoxy group or a group in which a plurality of alkyleneoxy groups are repeatedly linked together. The order of the alkylene group and the oxy group is not limited. The number of repetitions of the alkyleneoxy group is preferably 1 to 24, more preferably 1 to 12, and still more preferably 1 to 6. An alkylene group (preferably having 1 to 24 carbon atoms, more preferably 1 to 12 carbon atoms, and still more preferably 1 to 6 carbon atoms) may be interposed in the (poly)alkyleneoxy group in relation to the linkage with the ring Ar serving as a mother nucleus or a polymerizable group Q. Accordingly, the linking group may be a (poly)alkyleneoxy=alkylene group.

R³ is any substituent, and examples thereof include an alkyl group (preferably having 1 to 12 carbon atoms, more preferably 1 to 6 carbon atoms, and still more preferably 1 to 3 carbon atoms), an alkenyl group (preferably having 2 to 12 carbon atoms, more preferably 2 to 6 carbon atoms, and still more preferably 2 or 3 carbon atoms), an aryl group (preferably having 6 to 22 carbon atoms, more preferably 6 to 18 carbon atoms, and still more preferably 6 to 10 carbon atoms), an arylalkyl group (preferably having 7 to 23 carbon atoms, more preferably 7 to 19 carbon atoms, and still more preferably 7 to 11 carbon atoms), a hydroxy group, a carboxy group, an alkoxy group (preferably having 1 to 24 carbon atoms, more preferably 1 to 12 carbon atoms, and still more preferably 1 to 6 carbon atoms), an acyl group (preferably having 2 to 12 carbon atoms, more preferably 2 to 6 carbon atoms, and still more preferably 2 or 3 carbon atoms), and an aryloyl group (preferably having 7 to 23 carbon atoms, more preferably 7 to 19 carbon atoms, and still more preferably 7 to 11 carbon atoms).

L³ is a single bond or a linking group. Examples of the linking group include those of L¹ and L² described above.

n3 is preferably 3 or less, more preferably 2 or less, still more preferably 1 or less, and particularly preferably 0.

Q¹ and Q² are each independently a polymerizable group, and preferred examples thereof include those of the polymerizable group Qp described above.

In the ring-containing compound, an increase in the number of side chains having a polymerizable group enables the formation of a strong crosslinked structure at the time of curing and tends to improve the resolution. From this viewpoint, nq is preferably 2 or more. The upper limit is preferably 6 or less, more preferably 4 or less, and still more preferably 3 or less.

Similarly, from the viewpoint of easily forming a homogeneous crosslinked structure, when groups including a polymerizable group or substituents are introduced into the ring structure, the substituents are preferably arranged in series.

### Dendrimer-Type Compound

The other polymerizable compound may be a dendrimer-type compound. The dendrimer means a dendritic polymer having a structure that branches from the center in an ordered manner. The dendrimer is constituted by a central molecule (trunk) called a core and side chain moieties (branches) called dendrons. The dendrimer is generally a fan-shaped compound as a whole but may be a dendrimer in which dendrons extend in a semicircular or circular shape. A polymerizable compound can be obtained by introducing a group having a polymerizable group into a dendron moiety (for example, a terminal moiety away from the core) of the dendrimer. If a (meth)acryloyl group is used as the polymerizable group to be introduced, a dendrimer-type polyfunctional (meth)acrylate can be obtained.

A preferred range of the number of polymerizable groups in the dendrimer-type compound has been described above.

For the dendrimer-type compound, for example, the matters disclosed in JP5512970B can be referred to, and the description of the publication is cited and incorporated herein.

Examples of the other polymerizable compound include compounds described in paragraphs 0017 to 0024 and Examples of JP2014-090133A, compounds described in paragraphs 0024 to 0089 of JP2015-009171A, compounds described in paragraphs 0023 to 0037 of JP2015-070145A, and compounds described in paragraphs 0012 to 0039 of WO2016/152597A, which are cited and incorporated herein by reference.

The other polymerizable compound may be included in an amount of 10% by mass or more in the curable composition for imprinting. The upper limit is practically less than 30% by mass in relation to the other polymerizable compound. One or a plurality of other polymerizable compounds may be used. When a plurality of the other polymerizable compounds are used, the total amount thereof is within the range described above. Radical Generator

The curable composition for imprinting according to the present invention includes a radical generator.

The radical generator is preferably a thermal radical generator or a photo-radical generator, and a photo-radical generator is preferable from the viewpoint that the radical generator can be used in the photo-imprint method.

Any compound may be used as the photo-radical generator as long as the compound generates an active species for polymerizing the above-described polymerizable compound by light irradiation. In the present invention, a plurality of photo-radical generators may be used in combination.

The content of the radical generator used in the present invention is, for example, 0.01% to 15% by mass, preferably 0.1% to 12% by mass, and more preferably 0.2% to 7% by mass relative to the total solid content of the curable composition for imprinting. When two or more radical generators are used, the total amount thereof is preferably within the range described above.

A content of the radical generator of 0.01% by mass or more is preferable because sensitivity (rapid curability), resolution, line edge roughness, and coating film hardness tend to improve. On the other hand, a content of the radical generator of 15% by mass or less is preferable because, for example, light-transmitting properties, colorability, and handleability tend to improve.

For the thermal radical generator, components described in JP2013-036027A, JP2014-090133A, and JP2013-189537A can be used. With regard to, for example, the content, reference can be made to the description of the above publications.

The photo-radical generator used in the present invention may be, for example, a commercially available initiator. For example, those described in paragraph 0091 of JP2008-105414A can be preferably used as such examples. Of these, acetophenone compounds, phenylglyoxylate compounds, acylphosphine oxide compounds, and oxime ester compounds are preferred in view of curing sensitivity and absorption characteristics.

Preferred examples of the acetophenone compounds include hydroxyacetophenone compounds, dialkoxyacetophenone compounds, and aminoacetophenone compounds.

Preferred examples of the hydroxyacetophenone compounds include Irgacure (registered trademark) 2959 (1-[4-(2-hydroxyethoxy)phenyl]-2-hydroxy-2-methyl-1-propan-1-one), Irgacure (registered trademark) 184 (1-hydroxycyclohexyl phenyl ketone), Irgacure (registered trademark) 500 (1-hydroxycyclohexyl phenyl ketone, benzophenone), and Darocure (registered trademark) 1173 (2-hydroxy-2-methyl-1-phenyl-1-propan-1-one), which are available from BASF.

Preferred examples of the dialkoxyacetophenone compounds include Irgacure (registered trademark) 651 (2,2-dimethoxy-1,2-diphenylethan-1-one), which is available from BASF.

Preferred examples of the aminoacetophenone compounds include Irgacure (registered trademark) 369 (2 -b enzyl-2-dimethylamino-1-(4-morpholinophenyl) butanone-1), Irgacure (registered trademark) 379 (EG) (2-dimethylamino-2-(4-methylbenzyl)-1-(4-morpholin-4-yl-phenyl)butan-1-one), and Irgacure (registered trademark) 907 (2-methyl-1[4-(methylthio) phenyl]-2-(4-morpholinyl)-1-propanone), which are available from BASF.

Preferred examples of the phenylglyoxylate compounds include Irgacure (registered trademark) 754 and Darocure (registered trademark) MBF, which are available from BASF.

Preferred examples of the acylphosphine oxide compounds (polymerization initiators having an acylphosphine oxide group in the molecules) include Irgacure (registered trademark) 819 (bis(2,4,6-trimethylbenzoyl)-phenylphosphineoxide) and Irgacure (registered trademark) 1800 (bis (2,6-dimethoxyb enzoyl)-2,4,4-trimethyl-p entylphosphineoxide), which are available from BASF, and Lucirin TPO (2,4,6-trimethylbenzoyldiphenyl phosphine oxide) and Lucirin TPO-L (2,4,6-trimethylbenzoylphenylethoxy phosphine oxide), which are available from BASF.

Preferred examples of the oxime ester compounds include Irgacure (registered trademark) OXE01 (1,2-octanedione, 1-[4-(phenylthio)phenyl]-2-(0-benzoyloxime) and Irgacure (registered trademark) OXE02 (ethanone, 1-[9-ethyl-6-(2-methylbenzoyl)-9H-carbazol-3-yl]-, 1-(0-acetyloxime)), which are available from BASF.

Specific Compound Specific Compound 1

A curable composition for imprinting according to a first embodiment of the present invention includes a specific compound 1.

The specific compound 1 has a monovalent hydrocarbon group having 4 to 11 carbon atoms and a poly(oxyalkylene) group.

Poly(oxyalkylene) Group

The poly(oxyalkylene) group in the specific compound 1 is a group in which two or more oxyalkylene groups are directly bonded together.

The number of repetitions of oxyalkylene groups in the poly(oxyalkylene) group is preferably 4 to 40, more preferably 4 to 20, and still more preferably 4 to 15.

The oxyalkylene groups included in the poly(oxyalkylene) group may have the same structure or different structures.

When the poly(oxyalkylene) group includes two or more types of oxyalkylene groups having different structures, for example, the poly(oxyalkylene) group may be a group in which the two or more types of oxyalkylene groups having different structures are randomly bonded together, or may include a block of oxyalkylene groups having a certain structure and a block of oxyalkylene groups having another structure, and the arrangement of the oxyalkylene groups is not particularly limited.

The number of carbon atoms of the alkylene group in the poly(oxyalkylene) group is preferably 2 to 10, more preferably 2 to 4, and still more preferably 2 or 3.

The poly(oxyalkylene) group preferably includes an oxyalkylene group represented by the following formula (OA-1) and is more preferably a group consisting of an oxyalkylene group represented by the following formula (0A-1).

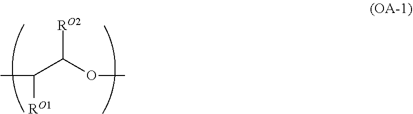

In formula (OA-1)), R^{O1} and R^{O2} each independently represent a hydrogen atom or a methyl group, but R^{O1} and R^{O2} do not simultaneously represent a methyl group.

The poly(oxyalkylene) group is preferably a poly(ethyleneoxy) group, a poly(ethyleneoxy-ran-propyleneoxy) group, or a poly(ethyleneoxy-block-propyleneoxy) group.

“Poly(A-ran-B)” indicates that A and B are randomly bonded together, and “poly(A-block-B)” indicates that a block formed from A and a block formed from B are bonded together.

The content of the poly(oxyalkylene) group in the specific compound 1 is preferably 30% to 90% by mass, more preferably 40% to 85% by mass, and still more preferably 50% to 75% by mass.

### Monovalent Hydrocarbon Group Having 4 to 11 Carbon Atoms

The monovalent hydrocarbon group having 4 to 11 carbon atoms in the specific compound 1 may be either an aromatic hydrocarbon group or an aliphatic hydrocarbon group, but is preferably an aliphatic hydrocarbon group, and more preferably an alkyl group.

The aliphatic hydrocarbon group or the alkyl group may have any of a linear structure, a branched structure, a cyclic structure, and a structure represented by bonding thereof, but preferably has a linear or branched structure.

Of these, the monovalent hydrocarbon group is preferably a linear alkyl group or a branched alkyl group.

The number of carbon atoms of the monovalent hydrocarbon group is 4 to 11, preferably 5 to 10, and more preferably 6 to 10.

The specific compound 1 may have only one such monovalent hydrocarbon group or two or more such monovalent hydrocarbon groups.

The number of the monovalent hydrocarbon groups in the specific compound 1 is preferably 1 or 2.

An embodiment in which the specific compound 1 has two monovalent hydrocarbon groups, each of which is the aforementioned monovalent hydrocarbon group, is also one of preferred embodiments of the present invention.

The monovalent hydrocarbon group is preferably directly bonded to the poly(oxyalkylene) group.

Some or all of hydrogen atoms of the monovalent hydrocarbon group are optionally substituted with halogen atoms. Examples of the halogen atoms include a fluorine atom, a chlorine atom, a bromine atom, and an iodine atom, and a fluorine atom or a chlorine atom is preferred, and a fluorine atom is more preferred.

An embodiment in which the monovalent hydrocarbon group is an unsubstituted hydrocarbon group is also one of preferred embodiments of the present invention.

Specific examples of the monovalent hydrocarbon group include, but are not limited to, the following groups. For example, linear alkyl groups having 4 to 11 carbon atoms and branched alkyl groups having 4 to 11 carbon atoms other than those shown below can also be used. In the following structures, * represents a bonding site to another structure.

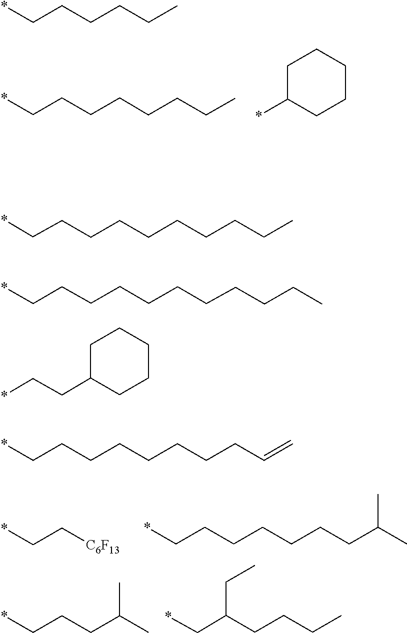

### Compound Represented by Formula (C-1)

The specific compound 1 is preferably a compound represented by the following formula (C-1).

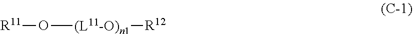

In formula (C-1), R¹¹ and R¹² each independently represent a hydrogen atom or a monovalent organic group, at least one of R¹¹ or R¹² is a monovalent hydrocarbon group having 4 to 11 carbon atoms, each L¹¹ independently represents an alkylene group, and n1 represents an integer of 2 or more.

In formula (C-1), R¹¹ and R¹² each independently represent a hydrogen atom or a monovalent organic group, and at least one of R¹¹ or R¹² is a monovalent organic group having 4 to 11 carbon atoms.

Preferred embodiments of the monovalent hydrocarbon group having 4 to 11 carbon atoms in R¹¹ and R¹² are the same as the preferred embodiments of the monovalent hydrocarbon group having 4 to 11 carbon atoms in the specific compound 1.

Examples of the monovalent organic group having 4 to 11 carbon atoms in R¹¹ and R¹² include a hydrocarbon group having 1 to 3 carbon atoms.

Preferably, R¹¹ and R¹² are each a monovalent hydrocarbon group having 4 to 11 carbon atoms, or one of R¹¹ and R¹² is a monovalent hydrocarbon group having 4 to 11 carbon atoms and the other is a hydrogen atom.

In formula (C-1), L^{H} is preferably an alkylene group having 2 to 10 carbon atoms, more preferably an alkylene group having 2 to 4 carbon atoms, and still more preferably an ethylene group or a propylene group.

In formula (C-1), n1 is preferably 4 or more, and more preferably 5 or more. n1 is preferably 40 or less, and more preferably 20 or less.

Specific Compound 2

A curable composition for imprinting according to a second embodiment of the present invention includes a specific compound 2.

The specific compound 2 is a compound represented by the following formula (C-2).

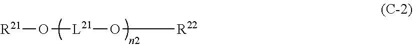

In formula (C-2), R²¹ and R²² each independently represent a monovalent hydrocarbon group, each L²′ independently represents an alkylene group, and n2 represents an integer of 2 or more.

In formula (C-2), each of the monovalent hydrocarbon groups in R²¹ and R²² may be either an aromatic hydrocarbon group or an aliphatic hydrocarbon group, but is preferably an aliphatic hydrocarbon group, and more preferably an alkyl group.

The aliphatic hydrocarbon group or the alkyl group may have any of a linear structure, a branched structure, a cyclic structure, and a structure represented by bonding thereof, but preferably has a linear or a branched structure.

Of these, the monovalent hydrocarbon group is preferably a linear alkyl group or a branched alkyl group.

The number of carbon atoms of each of the monovalent hydrocarbon groups in R21 and R²² is preferably 1 to 20, more preferably 4 to 11, still more preferably 5 to 10, and particularly preferably 6 to 10.

Some or all of hydrogen atoms of each of the monovalent hydrocarbon groups in R²¹ and R²² are optionally substituted with halogen atoms. Examples of the halogen atoms include a fluorine atom, a chlorine atom, a bromine atom, and an iodine atom, and a fluorine atom or a chlorine atom is preferred, and a fluorine atom is more preferred.

An embodiment in which the monovalent hydrocarbon group is an unsubstituted hydrocarbon group is also one of preferred embodiments of the present invention.

Furthermore, an embodiment in which at least one of R²¹ or R²² is a monovalent hydrocarbon group having 4 to 11 carbon atoms is also preferred. Preferred embodiments of the monovalent hydrocarbon group having 4 to 11 carbon atoms are the same as the preferred embodiments of the monovalent hydrocarbon group having 4 to 11 carbon atoms in the specific compound 1 described above.

In formula (C-2), preferred embodiments of L²¹ and n2 are the same as the preferred embodiments of L^{H} and n1, respectively, in formula (C-1).

Specific Compound

The weight-average molecular weight of the specific compound is preferably 300 to 1,000, more preferably 350 to 900, and still more preferably 400 to 800.

The ClogP value of the specific compound is preferably 1 to 10, more preferably 2 to 8, and still more preferably 3 to 7.

The absolute value of the difference between the ClogP value of the specific compound and the ClogP value of the organopolysiloxane having a radical polymerizable group is preferably 1 to 5, more preferably 1 to 4, and still more preferably 1 to 3.

As used herein, “ClogP” refers to logP (log [water/octanol partition coefficient]) predicted by calculation from the chemical structure. ClogP values used herein are calculated by ChemDraw Pro 20.1.

The specific compound preferably has a hydroxy group.

When the specific compound has a hydroxy group, the number of hydroxy groups in the specific compound is preferably 1 to 4, more preferably 1 to 3, and still more preferably 1 or 2.

Preferably, the specific compound has no radical polymerizable group so that the specific compound is likely to be unevenly distributed on the surface at the time of curing. Examples of the radical polymerizable group include the same groups as radical polymerizable groups in the above-described organopolysiloxane having a radical polymerizable group.

Specific examples of the specific compound include, but are not limited to, C-1 to C-20 in Examples described later.

The content of the specific compound is preferably 0.5% to 10% by mass, more preferably 0.6% to 5% by mass, and still more preferably 0.7 to 3% by mass relative to the total solid content of the composition.

The content of the specific compound relative to the total mass of the organopolysiloxane is preferably 0.5% to 10% by mass, more preferably 0.6% to 5% by mass, and still more preferably 0.7% to 3% by mass.

Mold Release Agent

The curable composition for imprinting according to the present invention may further include a mold release agent. However, a compound corresponding to the above-described specific compound does not correspond to the release agent. The content of the mold release agent is 0.1% by mass or more, preferably 0.3% by mass or more, more preferably 0.5% by mass or more, and still more preferably 0.6% by mass or more relative to the total solid content of the composition. The upper limit is less than 1.0% by mass, preferably 0.9% by mass or less, and more preferably 0.85% by mass or less. When the content of the mold release agent is equal to or more than the lower limit, mold releasability is satisfactory, and it is possible to prevent peeling of the cured film and mold damage during mold release. When the content is equal to or less than the upper limit, a good resolution can be realized without causing an excessive decrease in pattern strength at the time of curing due to the influence of the mold release agent.

One or a plurality of mold release agents may be used. When a plurality of mold release agents are used, the total amount thereof is within the range described above.

The type of mold release agent is not particularly limited, but the mold release agent preferably segregates at the interface with the mold and has a function of effectively promoting release from the mold. In the present invention, preferably, the mold release agent does not substantially contain fluorine atoms or silicon atoms. The phrase “does not substantially contain” means that the total amount of fluorine atoms and silicon atoms is 1% by mass or less, preferably 0.5% by mass or less, more preferably 0.1% by mass or less, and still more preferably 0.01% by mass or less of the mold release agent. It is preferable to use a mold release agent that does not substantially contain fluorine atoms or silicon atoms from the viewpoint of making the curable composition for imprinting excellent in process resistance to, for example, etching while realizing high mold releasability of a film thereof.

Specifically, the mold release agent used in the present invention is preferably a surfactant. Alternatively, the mold release agent is preferably an alcohol compound having at least one hydroxy group at a terminal or a compound having a (poly)alkylene glycol structure in which hydroxy groups are etherified ((poly)alkylene glycol compound). The surfactant and the (poly)alkylene glycol compound are preferably non-polymerizable compounds having no polymerizable groups Qp. The term “(poly)alkylene glycol” means that the (poly)alkylene glycol may have either a single alkylene glycol structure or a structure in which a plurality of alkylene glycol structures are repeatedly linked together.

### Surfactant

The surfactant that can be used as the mold release agent in the present invention is preferably a nonionic surfactant.

A nonionic surfactant is a compound having at least one hydrophobic moiety and at least one nonionic hydrophilic moiety. The hydrophobic moiety and the hydrophilic moiety may each be located at a terminal of the molecule or may be located inside the molecule. The hydrophobic moiety is composed of, for example, a hydrocarbon group, and the number of carbon atoms of the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxy group, a phenolic hydroxy group, ether groups (preferably a (poly)alkyleneoxy group and a cyclic ether group), an amide group, an imide group, a ureido group, a urethane group, a cyano group, a sulfonamide group, a lactone group, a lactam group, and a cyclocarbonate group. Of these, a compound having an alcoholic hydroxy group or an ether group (preferably a (poly)alkyleneoxy group or a cyclic ether group) is more preferred.

### Alcohol Compound and (Poly)alkylene Glycol Compound

A preferred mold release agent used in the curable composition for imprinting according to the present invention may be an alcohol compound having at least one hydroxy group at a terminal or a (poly)alkylene glycol compound in which hydroxy groups are etherified, as described above.

Specifically, the (poly)alkylene glycol compound preferably has an alkyleneoxy group or a polyalkyleneoxy group, and more preferably has a (poly)alkyleneoxy group including an alkylene group having 1 to 6 carbon atoms. Specifically, the (poly)alkylene glycol compound preferably has a (poly)ethyleneoxy group, a (poly)propyleneoxy group, a (poly)butyleneoxy group, or a mixed structure thereof, more preferably has a (poly)ethyleneoxy group, a (poly)propyleneoxy group, or a mixed structure thereof, and still more preferably has a (poly)propyleneoxy group. The (poly)alkylene glycol compound may be substantially composed only of a (poly)alkyleneoxy group except for a terminal substituent.

Herein, “substantially” means that the content of components other than the (poly)alkyleneoxy group is 5% by mass or less, and preferably 1% by mass or less, based on the total mass. In particular, a compound substantially composed only of a (poly)propyleneoxy group is preferably included as the (poly)alkylene glycol compound.

The number of repetitions of the alkyleneoxy group in the (poly)alkylene glycol compound is preferably 3 to 100, more preferably 4 to 50, still more preferably 5 to 30, and even more preferably 6 to 20.

In the (poly)alkylene glycol compound, as long as a hydroxy group at one terminal is etherified, the remaining terminal may be composed of a hydroxy group, or the hydrogen atom of the terminal hydroxy group may be substituted. The group with which the hydrogen atom of the terminal hydroxy group may be substituted is preferably an alkyl group (i.e., (poly)alkylene glycol alkyl ether) or an acyl group (i.e., a (poly)alkylene glycol ester). A compound having a plurality of (preferably two or three) (poly)alkylene glycol chains via a linking group can also be preferably used.

Preferred specific examples of the (poly)alkylene glycol compound include polyethylene glycol, polypropylene glycol (for example, manufactured by FUJIFILM Wako Pure Chemical Corporation), and mono- or dimethyl ethers, mono- or dicetyl ethers, monostearic acid esters, monooleic acid esters, polyoxyethylene glyceryl ethers, polyoxypropylene glyceryl ethers, polyoxyethylene lauryl ethers, and trimethyl ethers thereof

The (poly)alkylene glycol compound is preferably a compound represented by the following formula (P1) or (P2).

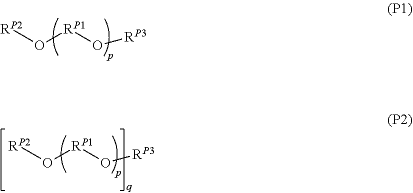

R^{P1} in the formulae is an alkylene group which may be chain-like or cyclic and may be linear or branched (and which preferably has 1 to 12 carbon atoms, more preferably 1 to 6 carbon atoms, and still more preferably 1 to 3 carbon atoms). R^{P2} and R^{P3} are each a hydrogen atom or an alkyl group which may be chain-like or cyclic and may be linear or branched and which has 1 to 3 or 12 or more carbon atoms (preferably has 1 to 3 or 12 to 36 carbon atoms, and more preferably 2 or 3 or 12 to 24 carbon atoms). However, in formula (P1), R^{P2} and R^{P3} do not simultaneously represent an alkyl group. p is preferably an integer of 1 to 24, and more preferably an integer of 2 to 12.

R^{P4} is a q-valent linking group, is preferably a linking group composed of an organic group, and is more preferably a linking group composed of a hydrocarbon. Specific examples of the linking group composed of a hydrocarbon include a linking group having an alkane structure (preferably having 1 to 24 carbon atoms, more preferably 2 to 12 carbon atoms, and still more preferably 2 to 6 carbon atoms), a linking group having an alkene structure (preferably having 2 to 24 carbon atoms, more preferably 2 to 12 carbon atoms, and still more preferably 2 to 6 carbon atoms), and a linking group having an aryl structure (preferably having 6 to 22 carbon atoms, more preferably 6 to 18 carbon atoms, and still more preferably 6 to 10 carbon atoms).

q is preferably an integer of 3 to 8, more preferably an integer of 3 to 6, and still more preferably an integer of 3 or 4.

The weight-average molecular weight of the alcohol compound or the (poly)alkylene glycol compound used as the mold release agent is preferably 150 to 6,000, more preferably 200 to 3,000, still more preferably 250 to 2,000, and even more preferably 300 to 1,200.

Examples of commercially available products of the (poly)alkylene glycol compound that can be used in the present invention include OLFINE E1010 (manufactured by Nissin Chemical Industry Co., Ltd.) and Brij35 (manufactured by Kishida Chemical Co., Ltd.). Polymerization Inhibitor

The curable composition for imprinting according to the present invention may include at least one polymerization inhibitor.

The polymerization inhibitor has a function of quenching (deactivating) a reactive substance such as a radical generated from a photopolymerization initiator, and plays a role of suppressing a reaction of the curable composition for imprinting at a low exposure dose.

In particular, when the other polymerizable compound is included, the polymerization inhibitor can be sufficiently dissolved, and the above effect is easily exhibited.

Examples of the polymerization inhibitor that are suitably used include hydroquinone, 4-methoxyphenol, di-tert-butyl-p-cresol, pyrogallol, p-tert-butylcatechol, 1,4-benzoquinone, diphenyl-p-benzoquinone, 4,4′-thiobis(3-methyl-6-tert-butylphenol), 2,T-methylenebis(4-methyl-6-tert-butylphenol), N-nitroso-N-phenylhydroxyamine aluminum salt, phenothiazine, N-nitrosodiphenylamine, N-phenylnaphthylamine, ethylenediaminetetraacetic acid, 1,2-cyclohexanediaminetetraacetic acid, glycol ether diaminetetraacetic acid, 2,6-di-tert-butyl methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-(1-naphthyl)hydroxyamine ammonium salt, and bis(4-hydroxy-3,5-tert-butyl)phenylmethane. In addition, polymerization inhibitors described in paragraph 0060 of JP2015-127817A and compounds described in paragraphs 0031 to 0046 of WO2015/125469A can also be used. Specific examples of commercially available products of the polymerization inhibitor include Q-1300, Q-1301, and TBHQ (manufactured by FUJIFILM Wako Pure Chemical Corporation), and Quino Power series (manufactured by Kawasaki Kasei Chemicals Ltd.).

In addition, the following compounds (where Me is a methyl group) can be used.

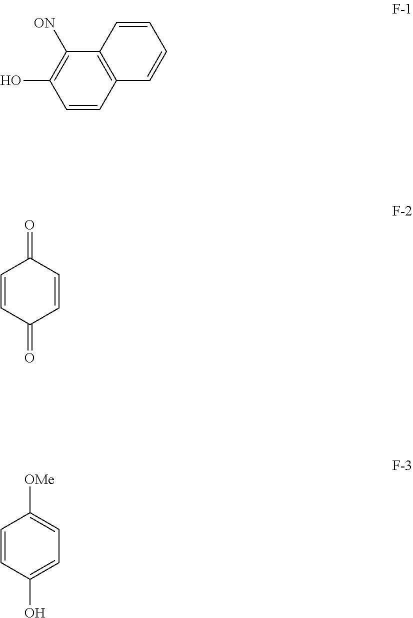

The content of the polymerization inhibitor is preferably 0.1% to 5% by mass, and more preferably 0.5% to 3% by mass. When the content is equal to or more than the lower limit, the reactivity of the photopolymerization initiator can be effectively exhibited. When the content is equal to or less than the upper limit, collapse of a transfer pattern is prevented, which enables effective patterning.

One or a plurality of polymerization inhibitors may be used. When a plurality of polymerization inhibitors are used, the total amount thereof is preferably within the range described above.

### Solvent

The curable composition for imprinting may include a solvent. The term “solvent” refers to a compound that is liquid at 23° C. and that has a boiling point of 250° C. or lower. In the case where the solvent is included, the content thereof is, for example, preferably 1% by mass or more, more preferably 10% by mass or more, and still more preferably 30% by mass or more.

The content is, for example, preferably 99.5% by mass or less, more preferably 99% by mass or less, and still more preferably 98% by mass or less.

An embodiment in which the content of the solvent relative to the total mass of the composition is 90% to 99% by mass is also one of preferred embodiments of the present invention. In the above embodiment, it is also preferable that the content of the solvent be 92% to 99% by mass or 94% to 99% by mass.

Only one solvent may be included, or two or more solvents may be included. When two or more solvents are included, the total amount thereof is preferably within the range described above.

In the present invention, the boiling point of the component having the highest content in the solvent is preferably 200° C. or lower, and more preferably 160° C. or lower. When the boiling point of the solvent is equal to or lower than the above temperature, the solvent in the curable composition for imprinting can be removed by baking. The lower limit of the boiling point of the solvent is not particularly limited, but is practically 60° C. or higher, and may be 80° C. or higher, or 100° C. or higher.

The solvent is preferably an organic solvent. The solvent is preferably a solvent having at least one of an ester group, a carbonyl group, an alkoxy group, a hydroxy group, or an ether group.

As specific examples of the solvent, an alkoxy alcohol, a propylene glycol monoalkyl ether carboxylate, a propylene glycol monoalkyl ether, a lactate, an acetate, a formate, an alkoxypropionic acid ester, a chain ketone, a cyclic ketone, a lactone, and an alkylene carbonate are selected.

Examples of the alkoxy alcohol include methoxyethanol, ethoxyethanol, methoxypropanol (such as 1-methoxy-2-propanol), ethoxypropanol (such as 1-ethoxy-2-propanol), propoxypropanol (such as 1-propoxy-2-propanol), methoxybutanol (such as 1-methoxy-2-butanol and 1-methoxy-3-butanol), ethoxybutanol (such as 1-ethoxy-2-butanol and 1-ethoxy-3-butanol), and methylpentanol (such as 4-methyl-2-pentanol).

The propylene glycol monoalkyl ether carboxylate is preferably at least one selected from the group consisting of propylene glycol monomethyl ether acetate, propylene glycol monomethyl ether propionate, and propylene glycol monoethyl ether acetate, and is particularly preferably propylene glycol monomethyl ether acetate.

The propylene glycol monoalkyl ether is preferably propylene glycol monomethyl ether or propylene glycol monoethyl ether.

The lactate is preferably ethyl lactate, butyl lactate, or propyl lactate.

The acetate or formate is preferably methyl acetate, ethyl acetate, butyl acetate, isobutyl acetate, propyl acetate, isoamyl acetate, methyl formate, ethyl formate, butyl formate, propyl formate, or 3-methoxybutyl acetate.

The alkoxypropionic acid ester is preferably methyl 3-methoxypropionate (MMP) or ethyl 3-ethoxypropionate (EEP).

The chain ketone is preferably 1-octanone, 2-octanone, 1-nonanone, 2-nonanone, acetone, 4-heptanone, 1-hexanone, 2-hexanone, diisobutyl ketone, phenylacetone, methyl ethyl ketone, methyl isobutyl ketone, acetylacetone, acetonylacetone, ionone, diacetonyl alcohol, acetyl carbinol, acetophenone, methyl naphthyl ketone, or methyl amyl ketone.

The cyclic ketone is preferably methylcyclohexanone, isophorone, or cyclohexanone.

The lactone is preferably y-butyrolactone (y-BL).

The alkylene carbonate is preferably propylene carbonate.

In addition to the components described above, an ester solvent having 7 or more carbon atoms (preferably 7 to 14 carbon atoms, more preferably 7 to 12 carbon atoms, and still more preferably 7 to 10 carbon atoms) and 2 or less heteroatoms is preferably used.

Preferred examples of the ester solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

It is also preferable to use a solvent having a flash point (hereinafter, also referred to as fp) of 30° C. or higher. As such a component (M2), propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 30° C.), pentyl acetate (fp: 45° C.), methyl 2-hydroxyisobutyrate (fp: 45° C.), γ-butyrolactone (fp: 101° C.), or propylene carbonate (fp: 132° C.) is preferred. Of these, propylene glycol monoethyl ether, ethyl lactate (EL), pentyl acetate, or cyclohexanone is more preferred, and propylene glycol monoethyl ether or ethyl lactate is particularly preferred. The term “flash point” as used herein means a value described in a reagent catalog of Tokyo Chemical Industry Co., Ltd. or Sigma-Aldrich Co. LLC.

The solvent is more preferably at least one selected from the group consisting of water, propylene glycol monomethyl ether acetate (PGMEA), ethoxy ethyl propionate, cyclohexanone, 2-heptanone, γ-butyrolactone, butyl acetate, propylene glycol monomethyl ether (PGME), ethyl lactate, and 4-methyl-2-pentanol, and still more preferably at least one selected from the group consisting of PGMEA and PGME.

### Ultraviolet Absorbent

The curable composition for imprinting according to the present invention may include an ultraviolet absorbent.

The ultraviolet absorbent absorbs leakage light (flare light) generated at the time of exposure to prevent reaction light from reaching the photopolymerization initiator, thus playing a role of inhibiting a reaction of the curable composition for imprinting at a low exposure dose.

Examples of the ultraviolet absorbent include benzotriazole-based, triazine-based, cyanoacrylate-based, benzophenone-based, and benzoate-based ultraviolet absorbents.

The content of the ultraviolet absorbent is preferably 0.01% to 5% by mass, and more preferably 0.02% to 3% by mass. One or a plurality of ultraviolet absorbents may be used.

When a plurality of ultraviolet absorbents are used, the total amount thereof is preferably within the range described above.

### Other Components

Other components can also be used in the curable composition for imprinting according to the present invention. For example, a sensitizer, an antioxidant, and the like may be included. The content is not particularly limited, but the other components may be appropriately blended in an amount of about 0.01% to 20% by mass based on the total solid content of the composition.

Specific examples of the other components included in the curable composition for imprinting according to the present invention include additives included in compositions described in JP2013-036027A, JP2014-090133A, and JP2013-189537A, the contents of which are incorporated herein. In addition, with regard to the preparation of the composition and the method for producing an imprint pattern, reference can be made to the description of the above publications, the contents of which are incorporated herein.

### Physical Properties

In the present invention, a modulus of elasticity of a cured film having a thickness of 300 nm and obtained by forming the curable composition for imprinting into a film and irradiating the film with light at an exposure dose of 300 mJ/cm², the modulus of elasticity being calculated by the Oliver-Pharr method, is preferably 1.5 GPa or more, more preferably 1.8 GPa or more, and still more preferably 2.0 GPa or more. The upper limit is practically 4.0 GPa or less.

When the modulus of elasticity of the cured film of the curable composition for imprinting is equal to or more than the lower limit, sufficient strength can be imparted to the imprint pattern, and the resolution is improved. On the other hand, when the modulus of elasticity is equal to or less than the upper limit, releasability from the mold is improved, and defects are reduced.

In the curable composition for imprinting according to the present invention, the difference between the surface tension of the total solid components and the surface tension of components excluding the mold release agent from the total solid components of the curable composition for imprinting is preferably 1.5 mN/m or less, more preferably 1.0 mN/m or less, and still more preferably 0.8 mN/m or less. The lower limit is, for example, 0.01 mN/m or more, and practically 0.1 mN/m or more. As this difference decreases, the compatibility of the mold release agent in the curable composition for imprinting is improved, and a homogeneous cured film can be formed.

### Storage Container

A known storage container can be used as a storage container for the curable composition for imprinting used in the present invention. As the storage container, it is also preferable to use a multi-layer bottle in which the inner wall of the container is formed of six layers composed of six types of resins or a bottle having a seven-layer structure composed of six types of resins for the purpose of suppressing the mixing of impurities into the raw materials or the composition. Examples of such a container include containers described in JP2015-123351A.

Coating Film and Method for Producing the Same

A film according to the present invention is a coating film of the curable composition for imprinting according to the present invention.

When the curable composition for imprinting according to the present invention includes a solvent, the solvent in the coating film according to the present invention may be removed by drying.

That is, the film according to the present invention is a film including an organopolysiloxane having a radical polymerizable group, a radical generator, a specific compound, and, if necessary, components other than the above components included in the above-described curable composition for imprinting according to the present invention, where the film may include a solvent or may include substantially no solvent.

The content of the solvent in the film according to the present invention is preferably 3% by mass or less, more preferably 1% by mass or less, and still more preferably 0.1% by mass or less relative to the total mass of the film. The lower limit of the content is not particularly limited, and may be 0% by mass.

The film according to the present invention is preferably formed by, for example, applying the curable composition for imprinting according to the present invention onto a support or a mold.

A method for producing a film according to the present invention includes a step of applying the curable composition for imprinting according to the present invention onto a support or a mold.

When the curable composition for imprinting according to the present invention includes a solvent, the method for producing a film according to the present invention preferably includes a step of applying the curable composition for imprinting according to the present invention onto a support or a mold, and a drying step of drying the applied curable composition for imprinting.

The details of the step of application and the drying step are the same as those of the application step and the drying step in a method for producing a pattern described below. Cured Product and Method for Producing Imprint Pattern

A cured product according to the present invention is a cured product obtained by curing the curable composition for imprinting according to the present invention.

The cured product according to the present invention is preferably a patterned cured product (imprint pattern).

A method for producing an imprint pattern will now be described.

### Method for Producing Imprint Pattern

A method for producing an imprint pattern according to the present invention includes an application step of applying the curable composition for imprinting according to the present invention to a member to be coated selected from the group consisting of a support and a mold,

a contact step of bringing, as a contact member, a member which is not selected as the member to be coated in the group consisting of the support and the mold into contact with the curable composition for imprinting,

a curing step of curing the curable composition for imprinting to form a cured product, and

a peeling step of peeling the mold and the cured product from each other.

### Application Step

The method for producing an imprint pattern according to the present invention includes an application step of applying the curable composition for imprinting according to the present invention to a member to be coated selected from the group consisting of a support and a mold.

In the application step, one member selected from the group consisting of a support and a mold is selected as a member to be coated, and the curable composition for imprinting according to the present invention is applied onto the selected member to be coated.

One selected from the group consisting of the support and the mold serves as a member to be coated, and the other serves as a contact member.

That is, in the application step, the curable composition for imprinting according to the present invention may be applied to a support and then brought into contact with a mold, or may be applied to a mold and then brought into contact with a support (which may have, for example, an adhesive layer described later).

### Support

With regard to the support, reference can be made to the description in paragraph 0103 of JP2010-109092A (corresponding US application is US2011/0183127A), the contents of which are incorporated herein. Specific examples thereof include silicon substrates, glass substrates, sapphire substrates, silicon carbide substrates, gallium nitride substrates, metallic aluminum substrates, amorphous aluminum oxide substrates, polycrystalline aluminum oxide substrates, and substrates made of GaAsP, GaP, AlGaAs, InGaN, GaN, AlGaN, ZnSe, AlGaInP, or ZnO. Specific examples of the material of the glass substrates include aluminosilicate glass, aluminoborosilicate glass, and barium borosilicate glass. In the present invention, the substrate is preferably a silicon substrate.

The support is preferably a member including an adhesive layer on a surface to which the curable composition for imprinting is to be applied.

The adhesive layer is preferably an adhesive layer formed by applying, to the support, a composition for forming an adhesive layer described below.

The support may further include a liquid film described below on a surface of the adhesive layer opposite to a surface in contact with the support.

The liquid film is preferably a liquid film formed by applying, onto the adhesive layer, a composition for forming a liquid film described below.

As the adhesive layer, for example, those described in paragraphs 0017 to 0068 of JP2014-024322A and paragraphs 0016 to 0044 of JP2013-093552A, adhesive layers described in JP2014-093385A, and adhesive layers described in JP2013-202982A can be used, and the contents thereof are incorporated herein.

### Mold

In the present invention, the mold is not particularly limited. With regard to the mold, reference can be made to the description in paragraphs 0105 to 0109 of JP2010-109092A (corresponding US application is US2011/0199592A), the contents of which are incorporated herein. The mold used in the present invention is preferably a quartz mold. The pattern (line width) of the mold used in the present invention preferably has a size of 50 nm or less. The pattern of the mold can be formed according to the desired processing accuracy by, for example, photolithography or an electron-beam drawing method; however, the method for producing a mold pattern is not particularly limited in the present invention.

A mold with which an imprint pattern including any shape of lines, holes, and pillars is formed as the imprint pattern is preferred.

In particular, a mold with which an imprint pattern including any shape of lines, holes, and pillars having a size of 100 nm or less is formed is preferred.

### Application Method

The method for applying the curable composition for imprinting according to the present invention to the member to be coated is not particularly specified, and generally well-known application methods can be employed. Examples thereof include a dip coating method, an air knife coating method, a curtain coating method, a wire bar coating method, a gravure coating method, an extrusion coating method, a spin coating method, a slit scan method, and an inkjet method.

Of these, an inkjet method and a spin coating method are preferred.

The curable composition for imprinting may be applied by multiple coatings.

In the method of disposing droplets by an inkjet method, the volume of each droplet is preferably about 1 to 20 pL, and the droplets are preferably disposed on a surface of the support at intervals. The interval between droplets may be appropriately determined according to the volume of each droplet, and an interval of 10 to 1,000 nm is preferred. In the case of the inkjet method, the interval between droplets is the interval between inkjet nozzles.

The inkjet method is advantageous in that the loss of the curable composition for imprinting is small.

Specific examples of the method for applying a curable composition for imprinting by an inkjet method include the methods described in, for example, JP2015-179807A and WO2016/152597A, and the methods described in these literatures can also be suitably employed in the present invention.

On the other hand, the spin coating method is advantageous in that the coating process is highly stable and the choice of usable materials is also widened.

Specific examples of the method for applying a curable composition for imprinting by a spin coating method include the methods described in, for example, JP2013-095833A and JP2015-071741A, and the methods described in these literatures can also be suitably employed in the present invention.

### Drying Step

The method for producing an imprint pattern according to the present invention may further include a drying step of drying the curable composition for imprinting according to the present invention applied in the application step.

In particular, when a composition including a solvent is used as the curable composition for imprinting according to the present invention, the method for producing an imprint pattern according to the present invention preferably includes a drying step.

In the drying step, at least a part of the solvent included in the applied curable composition for imprinting according to the present invention is removed.

The drying method is not particularly limited, and drying by heating, drying by air blowing, or the like can be used without particular limitation, and drying by heating is preferably performed.

The heating means is not particularly limited, and a publicly known hot plate, oven, infrared heater, or the like can be used.

In the present invention, the layer formed from the curable composition for imprinting after the application step and the optional drying step and before the contact step is also referred to as a “curable film”.

### Contact Step

The method for producing an imprint pattern according to the present invention includes a contact step of bringing, as a contact member, a member which is not selected as the member to be coated in the group consisting of the support and the mold into contact with the curable composition for imprinting (the curable film).

When a support is selected as the member to be coated in the application step, a mold serving as a contact member is brought into contact with the surface of the support to which the curable composition for imprinting according to the present invention has been applied (the surface on which the curable film has been formed) in the contact step.

When a mold is selected as the member to be coated in the application step, a support serving as a contact member is brought into contact with the surface of the mold to which the curable composition for imprinting according to the present invention has been applied (the surface on which the curable film has been formed) in the contact step.

That is, in the contact step, the curable composition for imprinting according to the present invention is present between the member to be coated and the contact member.

The details of the support and the mold are as described above.

When the curable composition for imprinting according to the present invention (the curable film) applied to the member to be coated is brought into contact with the contact member, a press contact pressure is preferably 1 MPa or less. When the press contact pressure is 1 MPa or less, the support and the mold are less likely to be deformed, and the pattern accuracy tends to improve. Furthermore, since the pressure applied is low, the size of the apparatus is likely to be reduced, which is also preferable.

It is also preferable that the contact between the curable film and the contact member be performed in an atmosphere containing helium gas or a condensable gas, or both helium gas and a condensable gas.

### Curing Step

The method for producing an imprint pattern according to the present invention includes a curing step of curing the curable composition for imprinting to form a cured product.

The curing step is performed after the contact step and before the peeing step. A method for producing a cured product according to the present invention includes a step of curing a curable composition for imprinting, the curable composition being obtained by a method for producing a curable composition for imprinting according to the present invention. The curing step can be performed by the same method as the curing step in the method for producing an imprint pattern according to the present invention. The cured product is preferably a cured product in a state in which the mold has been peeled off in the peeling step described later.

Examples of the curing method include curing by heating and curing by exposure. The curing method may be determined according to, for example, the type of polymerization initiator included in the curable composition for imprinting, but curing by exposure is preferred.

For example, in the case where the polymerization initiator is a photopolymerization initiator, the curable composition for imprinting can be cured by exposure in the curing step.

The exposure wavelength is not particularly limited and may be determined according to the polymerization initiator, and, for example, ultraviolet light can be used.

The exposure light source may be determined according to the exposure wavelength. Examples thereof include g-line (wavelength: 436 nm), h-line (wavelength: 405 nm), i-line (wavelength: 365 nm), broadband light (light including at least two wavelengths and selected from the group consisting of light having any of three wavelengths of g-line, h-line, and i-line, and a wavelength shorter than that of i-line, for example, a high-pressure mercury lamp in the case where no optical filter is used), semiconductor lasers (wavelength: 830 nm, 532 nm, 488 nm, 405 nm, etc.), metal halide lamps, excimer lasers, a KrF excimer laser (wavelength: 248 nm), an ArF excimer laser (wavelength: 193 nm), a F2 excimer laser (wavelength: 157 nm), extreme ultraviolet rays; EUV (wavelength: 13.6 nm), and electron beams.

Of these, exposure using i-line or broadband light is preferred.

The irradiation dose (exposure dose) at the time of exposure is sufficiently larger than the minimum irradiation dose necessary for curing the curable composition for imprinting. The irradiation dose necessary for curing the curable composition for imprinting can be appropriately determined by examining, for example, the amount of consumption of unsaturated bonds of the curable composition for imprinting.

The exposure dose is, for example, preferably in the range of 5 to 1,000 mJ/cm², and more preferably in the range of 10 to 500 mJ/cm².

The exposure illuminance is not particularly limited and may be selected depending on the relationship with the light source, but is preferably in the range of 1 to 500 mW/cm², and more preferably in the range of 10 to 400 mW/cm².

The exposure time is not particularly limited and may be determined in consideration of the exposure illuminance according to the exposure dose, but is preferably 0.01 to 10 seconds, and more preferably 0.5 to 1 second.

The temperature of the support at the time of exposure is usually room temperature, but the exposure may be performed while heating in order to enhance the reactivity. As a previous stage of the exposure, forming a vacuum state is effective in preventing inclusion of air bubbles, suppressing a decrease in reactivity due to inclusion of oxygen, and improving adhesiveness between the mold and the curable composition for imprinting; and therefore light irradiation may be performed in a vacuum state. The degree of vacuum at the time of exposure is preferably in the range from 10⁻¹ Pa to ordinary pressure.

After the exposure, the curable composition for imprinting after exposure may be heated as necessary. The heating temperature is preferably 150° C. to 280° C., and more preferably 200° C. to 250° C. The heating time is preferably 5 to 60 minutes, and more preferably 15 to 45 minutes.

In the curing step, only a heating step may be performed without performing exposure. For example, in the case where the polymerization initiator is a thermal polymerization initiator, the curable composition for imprinting can be cured by heating in the curing step. Preferred embodiments of the heating temperature and the heating time in such a case are the same as the heating temperature and the heating time in the case where heating is performed after exposure.

The heating means is not particularly limited and may be the same heating means as that for heating in the drying step described above.

Peeing Step

The method for producing an imprint pattern according to the present invention includes a peeling step of peeing the mold and the cured product from each other.

Through the peeling step, the cured product obtained in the curing step and the mold are peeled from each other to obtain a patterned cured product (also referred to as a “cured product pattern”) to which the pattern of the mold has been transferred. The obtained cured product pattern can be used in various applications as described below. The present invention is particularly advantageous in that a fine cured product pattern on the order of nanometers can be formed, and furthermore, a cured product pattern having a size of 50 nm or less, in particular, 30 nm or less can also be formed. The lower limit of the size of the cured product pattern is not particularly specified and may be, for example, 1 nm or more.

The peeling method is not particularly limited, and peeling can be performed using, for example, a mechanical peeling apparatus that is publicly known in a method for producing an imprint pattern.

Device, Method for Producing Device, Application of Cured Product Pattern

A device according to the present invention includes the cured product according to the present invention. The device according to the present invention is obtained by, for example, a method for producing a device according to the present invention described below.

The method for producing a device according to the present invention includes the method for producing an imprint pattern according to the present invention.

Specific examples thereof include a method for producing a device in which a pattern (cured product pattern) formed by the method for producing an imprint pattern according to the present invention is used as a permanent film used in, for example, a liquid crystal display device (LCD) or as an etching resist (mask for lithography) for producing a semiconductor element.

In particular, the present invention discloses a method for producing a circuit board, the method including a step of obtaining a pattern (cured product pattern) by the method for producing an imprint pattern according to the present invention, and a method for producing a device including the circuit board. Furthermore, the method for producing a circuit board according to a preferred embodiment of the present invention may have a step of subjecting a substrate to etching or ion implantation using, as a mask, a pattern (cured product pattern) obtained by the above method for forming a pattern, and a step of forming an electronic member. The circuit board is preferably a semiconductor element. That is, the present invention discloses a method for producing a semiconductor device, the method including the method for producing an imprint pattern according to the present invention. Furthermore, the present invention discloses a method for producing a device, the method having a step of obtaining a circuit board by the above method for producing a circuit board, and a step of connecting the circuit board to a control mechanism configured to control the circuit board.

In addition, by forming a grid pattern on a glass substrate of a liquid crystal display device using the method for producing an imprint pattern according to the present invention, a polarizing plate having a large screen size (for example, more than 55 inches or 60 inches) with little reflection or absorption can be produced at low cost. That is, the present invention discloses a method for producing a polarizing plate, the method including the method for producing an imprint pattern according to the present invention, and a method for producing a device including the polarizing plate. For example, polarizing plates described in JP2015-132825A and WO2011/132649A can be produced. Note that 1 inch is equal to 25.4 mm.

A pattern (cured product pattern) produced by the method for producing an imprint pattern according to the present invention is also useful as an etching resist (mask for lithography). That is, the present invention discloses a method for producing a device, the method including the method for producing an imprint pattern according to the present invention, in which the obtained cured product pattern is used as an etching resist.

When the cured product pattern is used as an etching resist, in an embodiment, first, a pattern (cured product pattern) may be formed on a support by applying the method for producing an imprint pattern according to the present invention, and the support may be etched using the obtained cured product pattern as an etching mask. By etching with, for example, hydrogen fluoride in the case of wet etching or an etching gas such as CF4 in the case of dry etching, a pattern conforming to the shape of the desired cured product pattern can be formed on the support.

The pattern (cured product pattern) produced by the method for producing an imprint pattern according to the present invention can also be preferably used for producing recording media such as magnetic disks; light-receiving elements such as solid-state imaging elements; light-emitting elements such as a light emitting diode (LED) and organic electroluminescence (organic EL); optical devices such as liquid crystal display devices (LCD); optical components such as diffraction gratings, relief holograms, optical waveguides, optical filters, and microlens arrays; flat-panel display members such as thin film transistors, organic transistors, color filters, antireflection films, polarizing plates, polarizing elements, optical films, and pillar materials; nanobiodevices; immunoassay chips; deoxyribonucleic acid (DNA) separation chips; microreactors; photonic liquid crystals; and guide patterns for directed self-assembly (DSA) of block copolymers, and the like.

That is, the present invention discloses a method for producing any of these devices, the method including the method for producing an imprint pattern according to the present invention.

### Composition for Forming Adhesive Layer

As described above, the formation of an adhesive layer between the support and the curable composition for imprinting provides an effect of, for example, improving the adhesiveness between the support and a layer of the curable composition for imprinting. In the present invention, the adhesive layer is obtained by applying a composition for forming an adhesive layer onto a support and then curing the composition in the same manner as in the curable composition for imprinting. Components of the composition for forming an adhesive layer will be described below.

The composition for forming an adhesive layer includes a curable component. The curable component is a component constituting the adhesive layer, and may be either a high-molecular-weight component (having a molecular weight of, for example, more than 1,000) or a low-molecular-weight component (having a molecular weight of, for example, less than 1,000). Specific examples thereof include resins and crosslinking agents. Each of these may be used alone or in combination of two or more thereof

The total content of the curable component in the composition for forming an adhesive layer is not particularly limited, but is preferably 50% by mass or more in the total solid content, more preferably 70% by mass or more in the total solid content, and still more preferably 80% by mass or more in the total solid content. The upper limit is not particularly limited, but is preferably 99.9% by mass or less.

The concentration of the curable component in the composition for forming an adhesive layer (the composition including a solvent) is not particularly limited, but is preferably 0.01% by mass or more, more preferably 0.05% by mass or more, and still more preferably 0.1% by mass or more. The upper limit is preferably 10% by mass or less, more preferably 5% by mass or less, still more preferably 1% by mass or less, and even more preferably less than 1% by mass.

### Resin

Publicly known resins can be widely used as the resin in the composition for forming an adhesive layer. The resin used in the present invention preferably has at least one of a radical polymerizable group or a polar group and more preferably has both a radical polymerizable group and a polar group.

When the resin has a radical polymerizable group, an adhesive layer with good strength is provided. When the resin has a polar group, adhesiveness to the support is improved. Furthermore, in the case where a crosslinking agent is blended, the crosslinked structure formed after curing can be made stronger to improve the strength of the resulting adhesive layer.

The radical polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group. A (meth)acryloyl group and a vinyl group are preferred, a (meth)acryloyl group is more preferred, and a (meth)acryloyloxy group is still more preferred. The ethylenically unsaturated bond-containing group defined here is referred to as Et.

The polar group is preferably at least one of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphate group, a carboxy group, or a hydroxy group, more preferably at least one of an alcoholic hydroxy group, a phenolic hydroxy group, or a carboxy group, and still more preferably an alcoholic hydroxy group or a carboxy group. The polar group defined here is referred to as a polar group Po. The polar group is preferably a nonionic group.

The resin in the composition for forming an adhesive layer may further include a cyclic ether group. Examples of the cyclic ether group include an epoxy group and an oxetanyl group, and an epoxy group is preferred. The cyclic ether group defined here is referred to as a cyclic ether group Cyt.

Examples of the resin include (meth)acrylic resins, vinyl resins, novolac resins, phenolic resins, melamine resins, urea resins, epoxy resins, and polyimide resins. The resin is preferably at least one of a (meth)acrylic resin, a vinyl resin, or a novolac resin.

The weight-average molecular weight of the resin is preferably 4,000 or more, more preferably 6,000 or more, and still more preferably 8,000 or more. The upper limit is preferably 1,000,000 or less, and may be 500,000 or less.

The resin preferably has at least one of constitutional units represented by the following formulae (1) to (3).

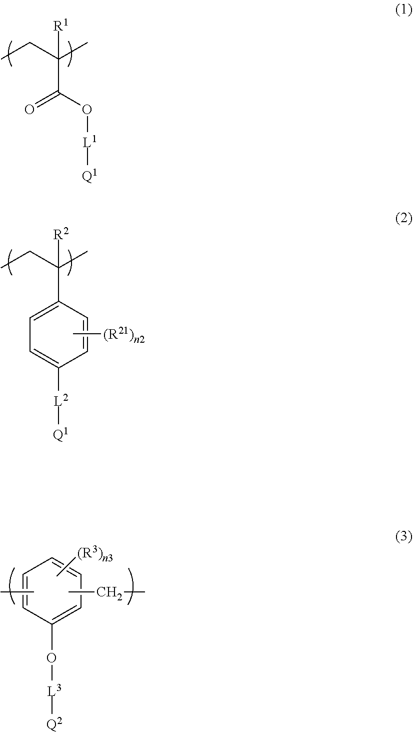

In the formulae, R¹ and R² are each independently a hydrogen atom or a methyl group. R²¹ and R³ are each independently a substituent. L′, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are preferably methyl groups.

R²¹ and R³ are each independently preferably the substituent described above.

When a plurality of R²¹ are present, they may be linked together to form a ring structure. In the present specification, the term “link” means not only a continuous form in which atoms are bonded together but also a condensed (fused ring) form in which some of the atoms are lost. Unless otherwise specified, an oxygen atom, a sulfur atom, or a nitrogen atom (amino group) may be contained in the linked ring structure. Examples of the ring structure to be formed include aliphatic hydrocarbon rings (the following given as examples are referred to as ring Cf) (e.g., a cyclopropyl group, a cyclobutyl group, a cyclopentyl group, a cyclohexyl group, a cyclopropenyl group, a cyclobutenyl group, a cyclopentenyl group, and a cyclohexenyl group), aromatic hydrocarbon rings (the following given as examples are referred to as ring Cr) (e.g., a benzene ring, a naphthalene ring, an anthracene ring, and a phenanthrene ring), nitrogen-containing heterocycles (the following given as examples are referred to as ring Cn) (e.g., a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, and a morpholine ring), oxygen-containing heterocycles (the following given as examples are referred to as ring Co) (e.g., a furan ring, a pyran ring, an oxirane ring, an oxetane ring, a tetrahydrofuran ring, a tetrahydropyran ring, and a dioxane ring), and sulfur-containing heterocycles (the following given as examples are referred to as ring Cs) (e.g., a thiophene ring, a thiirane ring, a thietane ring, a tetrahydrothiophene ring, and a tetrahydrothiopyran ring).

When a plurality of R³ are present, they may be linked together to form a ring structure. Examples of the ring structure to be formed include ring Cf, ring Cr, ring Cn, ring Co, and ring Cs.

L¹, L², and L³ are each independently preferably a single bond or a linking group L described below. In particular, a single bond, or an alkylene group or (oligo)alkyleneoxy group defined by the linking group L is preferred, and an alkylene group is more preferred. The linking group L preferably has the polar group Po as a substituent. An embodiment in which an alkylene group has a hydroxy group as a substituent is also preferred. In the present specification, the term “(oligo)alkyleneoxy group” means a divalent linking group having at least one “alkyleneoxy” which is a constitutional unit. The number of carbon atoms of the alkylene chain in the constitutional unit may be the same or different for each constitutional unit.

n2 is preferably 0 or 1, and more preferably 0. n3 is preferably 0 or 1, and more preferably 0.

Q¹ is preferably the ethylenically unsaturated bond-containing group Et.

Q² is preferably a polar group, and preferably an alkyl group having an alcoholic hydroxy group.

The resin may further include at least one constitutional unit selected from the group consisting of the following constitutional units (11), (21), and (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

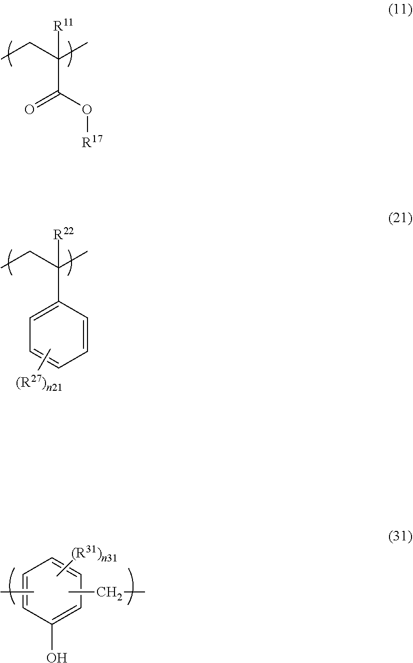

In the formulae, R¹¹ and R²² are each independently a hydrogen atom or a methyl group. R¹⁷ is a substituent. R²⁷ is a substituent. n21 is an integer of 0 to 5. R³¹ is a substituent, and n31 is an integer of 0 to 3.

R¹¹ and R²² are preferably methyl groups.

R¹⁷ is preferably a group including a polar group or a group including a cyclic ether group. When R¹⁷ is a group including a polar group, R¹⁷ is preferably a group including the polar group Po described above, and more preferably the polar group Po or a substituent substituted with the polar group Po. When R¹⁷ is a group including a cyclic ether group, R¹⁷ is preferably a group including the cyclic ether group Cyt described above, and more preferably a substituent substituted with the cyclic ether group Cyt.

R²⁷ is a publicly known substituent, and at least one R²⁷ is preferably a polar group. n21 is preferably 0 or 1, and more preferably 0. When a plurality of R²⁷ are present, they may be linked together to form a ring structure. Examples of the ring structure to be formed include examples of ring Cf, ring Cr, ring Cn, ring Co, and ring Cs.

R³¹ is preferably a publicly known substituent. n31 is an integer of 0 to 3, preferably 0 or 1, and more preferably 0. When a plurality of R³¹ are present, they may be linked together to form a ring structure. Examples of the ring structure to be formed include examples of ring Cf, ring Cr, ring Cn, ring Co, and ring Cs.

Examples of the linking group L include an alkylene group (preferably having 1 to 24 carbon atoms, more preferably 1 to 12 carbon atoms, and still more preferably 1 to 6 carbon atoms), an alkenylene group (preferably having 2 to 12 carbon atoms, more preferably 2 to 6 carbon atoms, and still more preferably 2 to 3 carbon atoms), an (oligo)alkyleneoxy group (preferably having 1 to 12 carbon atoms, more preferably 1 to 6 carbon atoms, and still more preferably 1 to 3 carbon atoms of an alkylene group in one constitutional unit, and preferably having a number of repetitions of 1 to 50, more preferably 1 to 40, and still more preferably 1 to 30), an arylene group (preferably having 6 to 22 carbon atoms, more preferably 6 to 18 carbon atoms, and still more preferably 6 to 10 carbon atoms), an oxygen atom, a sulfur atom, a sulfonyl group, a carbonyl group, a thiocarbonyl group, —NR^{N}—, and linking groups formed by a combination thereof. The alkylene group, the alkenylene group, and the alkyleneoxy group may have a substituent. For example, the alkylene group may have a hydroxy group.

The linking chain length of the linking group L is preferably 1 to 24, more preferably 1 to 12, and still more preferably 1 to 6. The linking chain length means the number of atoms located on the shortest path among atomic groups involved in the linking. For example, in the case of —CH₂—(C=O)—O—, the linking chain length is 3.

The alkylene group, the alkenylene group, and the (oligo)alkyleneoxy group defined as the linking group L may be chain-like or cyclic, and may be linear or branched.

The atoms constituting the linking group L preferably include a carbon atom and a hydrogen atom, and if necessary, a heteroatom (for example, at least one selected from the group consisting of an oxygen atom, a nitrogen atom, and a sulfur atom). The number of carbon atoms in the linking group is preferably 1 to 24, more preferably 1 to 12, and still more preferably 1 to 6. The number of hydrogen atoms may be determined in accordance with the number of carbon atoms and the like. The numbers of heteroatoms, i.e., the number of oxygen atoms, the number of nitrogen atoms, and the number of sulfur atoms are each independently preferably 0 to 12, more preferably 0 to 6, and still more preferably 0 to 3.

The resin may be synthesized by a typical method. For example, the resin having the constitutional unit represented by formula (1) can be appropriately synthesized by a publicly known method relating to addition polymerization of an olefin. The resin having the constitutional unit represented by formula (2) can be appropriately synthesized by a publicly known method relating to addition polymerization of styrene. The resin having the constitutional unit represented by formula (3) can be appropriately synthesized by a publicly known method relating to the synthesis of a phenolic resin.

The above resins may be used alone or in combination of two or more thereof

In addition to the resins described above, resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used as the resin serving as the curable component, and the contents thereof are incorporated herein. Crosslinking Agent

The crosslinking agent in the composition for forming an adhesive layer is not particularly limited as long as the crosslinking agent promotes curing by crosslinking reaction. In the present invention, the crosslinking agent preferably forms a crosslinked structure due to a reaction with a polar group in the resin. The use of such a crosslinking agent causes the resin to be more strongly bonded to provide a stronger film.

Examples of the crosslinking agent include epoxy compounds (compounds having an epoxy group), oxetanyl compounds (compounds having an oxetanyl group), alkoxymethyl compounds (compounds having an alkoxymethyl group), methylol compounds (compounds having a methylol group), and blocked isocyanate compounds (compounds having a blocked isocyanate group). Alkoxymethyl compounds (compounds having an alkoxymethyl group) are preferred because strong bonds can be formed at low temperatures.

Other Components

The composition for forming an adhesive layer may include other components in addition to the components described above.

Specifically, the composition for forming an adhesive layer may include at least one of, for example, a solvent, a thermal acid generator, an alkylene glycol compound, a polymerization initiator, a polymerization inhibitor, an antioxidant, a leveling agent, a thickener, or a surfactant. With regard to the above components, components described in JP2013-036027A, JP2014-090133A, and JP2013-189537A can be used. With regard to, for example, the content, reference can be made to the description of the above publications. Solvent

In the present invention, the composition for forming an adhesive layer particularly preferably includes a solvent (hereinafter, also referred to as a “solvent for an adhesive layer”). The solvent is preferably, for example, a compound that is liquid at 23° C. and that has a boiling point of 250° C. or lower. The composition for forming an adhesive layer includes the solvent for an adhesive layer in an amount of preferably 99.0% by mass or more, more preferably 99.2% by mass or more, and may include the solvent for an adhesive layer in an amount of 99.4% by mass or more. That is, the total solid content concentration of the composition for forming an adhesive layer is preferably 1% by mass or less, more preferably 0.8% by mass or less, and still more preferably 0.6% by mass or less. The lower limit is preferably more than 0% by mass, more preferably 0.001% by mass or more, still more preferably 0.01% by mass or more, and even more preferably 0.1% by mass or more. When the proportion of the solvent is within the range described above, the film thickness at the time of film formation is kept small, and pattern formability in an etching process tends to improve.

Only one solvent or two or more solvents may be included in the composition for forming an adhesive layer. When two or more solvents are included, the total amount thereof is preferably within the range described above.

The boiling point of the solvent for an adhesive layer is preferably 230° C. or lower, more preferably 200° C. or lower, still more preferably 180° C. or lower, even more preferably 160° C. or lower, and yet still more preferably 130° C. or lower. The lower limit is preferably 23° C., and more preferably 60° C. or higher. A boiling point within the range described above is preferred because the solvent can be easily removed from the adhesive layer.

The solvent for an adhesive layer is preferably an organic solvent. The solvent is preferably a solvent having at least one of an ester group, a carbonyl group, a hydroxy group, or an ether group. Of these, an aprotic polar solvent is preferably used.

Of these, preferred examples of the solvent for an adhesive layer include alkoxy alcohols, propylene glycol monoalkyl ether carboxylates, propylene glycol monoalkyl ethers, lactates, acetates, alkoxypropionic acid esters, chain ketones, cyclic ketones, lactones, and alkylene carbonates. Propylene glycol monoalkyl ethers and lactones are particularly preferred.

### Composition for Forming Liquid Film

In the present invention, it is also preferable to form a liquid film on the adhesive layer using a composition for forming a liquid film, the composition including a radical polymerizable compound that is liquid at 23° C. and 1 atm. In the present invention, the liquid film is obtained by applying a composition for forming a liquid film onto a support and then drying the composition in the same manner as in the curable composition for imprinting. The formation of such a liquid film provides an effect of further improving the adhesiveness between the support and the curable composition for imprinting, and also improving the wettability of the curable composition for imprinting on the support. The composition for forming a liquid film will be described below.

The viscosity of the composition for forming a liquid film is preferably 1,000 mPa·s or less, more preferably 800 mPas or less, still more preferably 500 mPas or less, and even more preferably 100 mPas or less. The lower limit of the viscosity is not particularly limited, and may be, for example, 1 mPas or more. The viscosity is measured according to the following method.

The viscosity is measured using an E-type rotational viscometer RE85L manufactured by Toki Sangyo Co., Ltd. and a standard cone rotor (1° 34′ 8 R24) while the temperature of a sample cup is adjusted to 23° C. The viscosity is represented in units of mPas. Other details regarding the measurement are based on JISZ8803:2011. Two samples are prepared for one level, and each sample is measured three times. The arithmetic mean value of the total of six measurements is adopted as the evaluation value.

### Radical Polymerizable Compound A

The composition for forming a liquid film includes a radical polymerizable compound (radical polymerizable compound A) which is liquid at 23° C. and 1 atm.

The viscosity of the radical polymerizable compound A at 23° C. is preferably 1 to 100,000 mPas. The lower limit is preferably 5 mPas or more, and more preferably 11 mPas or more. The upper limit is preferably 1,000 mPas or less, and more preferably 600 mPas or less.

The radical polymerizable compound A may be a monofunctional radical polymerizable compound having only one radical polymerizable group in one molecule, or may be a polyfunctional radical polymerizable compound having two or more radical polymerizable groups in one molecule. A monofunctional radical polymerizable compound and a polyfunctional radical polymerizable compound may be used in combination. In particular, the radical polymerizable compound A included in the composition for forming a liquid film preferably includes a polyfunctional radical polymerizable compound, more preferably includes a radical polymerizable compound including 2 to 5 radical polymerizable groups in one molecule, still more preferably includes a radical polymerizable compound including 2 to 4 radical polymerizable groups in one molecule, and particularly preferably includes a radical polymerizable compound including two radical polymerizable groups in one molecule, for the reason of suppressing pattern collapse.

The radical polymerizable compound A preferably includes at least one of an aromatic ring (preferably having 6 to 22 carbon atoms, more preferably 6 to 18 carbon atoms, and still more preferably 6 to 10 carbon atoms) or an alicyclic ring (preferably having 3 to 24 carbon atoms, more preferably 3 to 18 carbon atoms, and still more preferably 3 to 6 carbon atoms) and more preferably includes an aromatic ring. The aromatic ring is preferably a benzene ring. The radical polymerizable compound A preferably has a molecular weight of 100 to 900.

Examples of radical polymerizable groups in the radical polymerizable compound A include ethylenically unsaturated bond-containing groups such as a vinyl group, an allyl group, and a (meth)acryloyl group, and a (meth)acryloyl group is preferred.

The radical polymerizable compound A is also preferably a compound represented by the following formula (I-1).

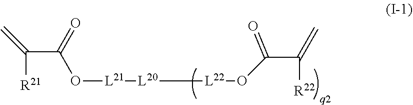

L²⁰ is a 1+q2 valent linking group, and examples thereof include 1+q2 valent linking groups including a group having an alkane structure (preferably having 1 to 12 carbon atoms, more preferably 1 to 6 carbon atoms, and still more preferably 1 to 3 carbon atoms), a group having an alkene structure (preferably having 2 to 12 carbon atoms, more preferably 2 to 6 carbon atoms, and still more preferably 2 or 3 carbon atoms), a group having an aryl structure (preferably having 6 to 22 carbon atoms, more preferably 6 to 18 carbon atoms, and still more preferably 6 to 10 carbon atoms), a group having a heteroaryl structure (preferably having 1 to 22 carbon atoms, more preferably 1 to 18 carbon atoms, and still more preferably 1 to 10 carbon atoms, where examples of heteroatoms include a nitrogen atom, a sulfur atom, and an oxygen atom, and a five-membered ring, a six-membered ring, or a seven-membered ring is preferred), or a group of a combination of the foregoing. Examples of the group of a combination of two aryl groups include groups having a structure of biphenyl, diphenylalkane, biphenylene, indene, or the like. Examples of the group of a combination of a group having a heteroaryl structure and a group having an aryl structure include groups having a structure of indole, benzimidazole, quinoxaline, carbazole, or the like.

L²⁰ is preferably a linking group including at least one selected from the group consisting of a group having an aryl structure and a group having a heteroaryl structure, and more preferably a linking group including a group having an aryl structure.

R²¹ and R²² each independently represent a hydrogen atom or a methyl group.

L²¹ and L²² each independently represent a single bond or the linking group L and are preferably a single bond or an alkylene group.

L²⁰ and L²¹ or L²² may be bonded together with or without the linking group L therebetween to form a ring. L²⁰, L²¹, and L²² may have a substituent. A plurality of substituents may be bonded together to form a ring. When a plurality of substituents are present, they may be the same or different from each other.

q2 is an integer of 0 to 5, preferably an integer of 0 to 3, more preferably an integer of 0 to 2, still more preferably 0 or 1, and particularly preferably 1.

As the radical polymerizable compound A, compounds described in paragraphs 0017 to 0024 and Examples of JP2014-090133A, compounds described in paragraphs 0024 to 0089 of JP2015-009171A, compounds described in paragraphs 0023 to 0037 of JP2015-070145A, and compounds described in paragraphs 0012 to 0039 of WO2016/152597A can also be used.

The content of the radical polymerizable compound A in the composition for forming a liquid film is preferably 0.01% by mass or more, more preferably 0.05% by mass or more, and still more preferably 0.1% by mass or more. The upper limit is preferably 10% by mass or less, more preferably 5% by mass or less, and still more preferably 1% by mass or less.

The content of the radical polymerizable compound A based on the solid content of the composition for forming a liquid film is preferably 50% by mass or more, more preferably 75% by mass or more, and still more preferably 90% by mass or more. The upper limit may be 100% by mass. Such radical polymerizable compounds A may be used alone or in combination of two or more thereof. When two or more radical polymerizable compounds A are used, the total amount thereof is preferably within the range described above.

It is also preferable that the solid component of the composition for forming a liquid film be substantially composed only of the radical polymerizable compound A. The case where the solid component of the composition for forming a liquid film is substantially composed only of the radical polymerizable compound A means that the content of the radical polymerizable compound A based on the solid content of the composition for forming a liquid film is 99.9% by mass or more, more preferably 99.99% by mass or more, and still more preferably, the solid component is composed only of the polymerizable compound A.

### Solvent

The composition for forming a liquid film preferably includes a solvent (hereinafter may be referred to as a “solvent for a liquid film”). Examples of the solvent for a liquid film include those described in the section of the solvent for an adhesive layer, and those solvents can be used. The composition for forming a liquid film includes the solvent for a liquid film in an amount of preferably 90% by mass or more, more preferably 99% by mass or more, and may include the solvent for a liquid film in an amount of 99.99% by mass or more.

The boiling point of the solvent for a liquid film is preferably 230° C. or lower, more preferably 200° C. or lower, still more preferably 180° C. or lower, even more preferably 160° C. or lower, and yet still more preferably 130° C. or lower. The lower limit is preferably 23° C., and more preferably 60° C. or higher. A boiling point within the range described above is preferred because the solvent can be easily removed from the liquid film.

### Radical Polymerization Initiator

The composition for forming a liquid film may include a radical polymerization initiator. Examples of the radical polymerization initiator include thermal radical polymerization initiators and photo-radical polymerization initiators, and a photo-radical polymerization initiator is preferred. As the photo-radical polymerization initiator, any publicly known compound can be used. Examples thereof include halogenated hydrocarbon derivatives (such as a compound having a triazine skeleton, a compound having an oxadiazole skeleton, and a compound having a trihalomethyl group), acylphosphine compounds, hexaarylbiimidazole compounds, oxime compounds, organic peroxides, thio compounds, ketone compounds, aromatic onium salts, acetophenone compounds, azo compounds, azide compounds, metallocene compounds, organoboron compounds, and iron-arene complexes. For the details of these, reference can be made to the description in paragraphs 0165 to 0182 of JP2016-027357A, the contents of which are incorporated herein. Of these, acetophenone compounds, acylphosphine compounds, and oxime compounds are preferred. Examples of commercially available products include IRGACURE-OXE01, IRGACURE-OXE02, IRGACURE-127, IRGACURE-819, IRGACURE-379, IRGACURE-369, IRGACURE-754, IRGACURE-1800, IRGACURE-651, IRGACURE-907, IRGACURE-TPO, and IRGACURE-1173 (all of which are manufactured by BASF), and Omnirad 184, Omnirad TPO H, Omnirad 819, and Omnirad 1173 (all of which are manufactured by I.G.M Resins B.V.).

When a radical polymerization initiator is included, the content thereof is preferably 0.1% to 10% by mass, more preferably 1% to 8% by mass, and still more preferably 2% to 5% by mass based on the solid content of the composition for forming a liquid film. When two or more radical polymerization initiators are used, the total amount thereof is preferably in the range described above.

### Other Components

In addition to the above, the composition for forming a liquid film may include at least one of, for example, a polymerization inhibitor, an antioxidant, a leveling agent, a thickener, or a surfactant.

### EXAMPLES

Hereafter, the present invention will be more specifically described with reference to Examples. The materials, amounts thereof used, proportions, details of processes, procedures thereof, and the like described in the following Examples may be appropriately changed without departing from the gist of the present invention. Accordingly, the scope of the present invention is not limited to specific examples described below.

### Preparation of Curable Composition for Imprinting

Various compounds shown in tables were mixed, and 4-hydroxy-2,2,6,6-tetramethylpiperidine-1-oxyl free radical (manufactured by Tokyo Chemical Industry Co., Ltd.) was further added as a polymerization inhibitor such that the amount thereof was 200 ppm by mass (0.02% by mass) based on the total amount of polymerizable compounds. In the tables below, A-1 to A-6 correspond to the polymerizable compounds. The components in the rows with “² in the tables were not used. The solvent shown in the tables was used, and the amount of solvent added was determined such that the concentration of non-volatile components (concentration of solid contents) of the composition became the value of “concentration of non-volatile component (mass %)” in the tables. Each of the resulting mixtures was filtered through a 0.02 um Nylon filter and a 0.003 um UPE filter to prepare curable compositions for imprinting.

### Method for Measuring Molecular Weight of Polymerizable Compound

The weight-average molecular weight (Mw) of a resin was defined as a value in terms of polystyrene according to gel permeation chromatography (GPC measurement). The apparatus used was HLC-8220 (manufactured by Tosoh Corporation), and columns used were a guard column HZ-L, TSKgel Super HZM-M, TSKgel Super HZ4000, TSKgel Super HZ3000, and TSKgel Super HZ2000 (manufactured by Tosoh Corporation). Tetrahydrofuran (THF) was used as an eluant. A detector at a wavelength of 254 nm of UV rays (ultraviolet rays) was used for the detection.

The weight-average molecular weight Mw of a low-molecular-weight compound having a molecular weight of less than 1,500 was measured with a liquid chromatography mass spectrometer (LC-MS). The conditions were as follows.
Apparatus: LC/MS G1956B, manufactured by Agilent Technologies
Column: TOSOH ODS-80 Ts
Mobile phases: 10 mM aqueous ammonium acetate solution/10 mM acetic acid methanol
aqueous solution
Flow rate: 0.2 mL/min
Amount of injection: 2 μL
Column temperature: 40° C.
Detector: ESI-Posi-SIM mode
Evaluation of Mold Release Force

The composition for forming an adhesive layer described in Example 6 of JP2014-24322A was applied onto a silicon wafer by spin coating and heated with a hot plate at 220° C. for one minute to form an adhesive layer having a thickness of 5 nm. Furthermore, the curable composition for imprinting was applied onto the adhesive layer by spin coating and heated with a hot plate at 80° C. for one minute to obtain a pattern forming layer having a film thickness of 53 nm in Example 43, a film thickness of 107 nm in Example 44, or a film thickness of 80 nm in the other examples. Next, a quartz mold (having a line pattern with a width of a mold protruding portion of 40 nm, a width of a mold recessed portion of 20 nm, and a depth of 50 nm in Example 43; a line pattern with a width of a mold protruding portion of 20 nm, a width of a mold recessed portion of 40 nm, and a depth of 50 nm in Example 44; or a line pattern with a width of a mold protruding portion of 20 nm, a width of a mold recessed portion of 20 nm, and a depth of 50 nm in other examples) was pressed against the pattern forming layer in a He atmosphere (replacement rate: 90% or more) to fill the mold with the curable composition for imprinting. At the time when 10 seconds passed after the press contact, exposure was performed from the mold side using a high-pressure mercury lamp under the conditions of a maximum wavelength of the irradiation light source of 365 nm, an exposure illuminance of 10 mW/cm², and an exposure time of 15 seconds (exposure dose: 150 mJ/cm²), and the mold was then peeled off to transfer the pattern to the pattern forming layer. The mold release force required for peeling was measured with a load cell. The mold release force was evaluated in accordance with the following evaluation criteria. The evaluation results are shown in the row of “Evaluation of mold release force” in the tables. Evaluation Criteria
A: mold release force <15 N
B: 15 N<mold release force <20 N
C: 20 N<mold release force <25 N
D: mold release force >25 N

TABLE 1

| | | Example | | | | | | | |
|---|---|---|---|---|---|---|---|---|---|
| | | 1 | 2 | 3 | 4 | 5 | 6 | 7 | 8 |
| Composition | A-1 | 96 | 96 | 96 | 96 | 96 | 96.7 | 82 | 96 |
| | A-2 | — | — | — | — | — | — | — | — |
| | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | B-1 | 3 | 3 | 3 | 3 | 3 | 3 | 3 | 3 |
| | B-2 | — | — | — | — | — | — | — | — |
| | B-3 | — | — | — | — | — | — | — | — |
| | B-4 | — | — | — | — | — | — | — | — |
| | B-5 | — | — | — | — | — | — | — | — |
| | B-6 | — | — | — | — | — | — | — | — |
| | B-7 | — | — | — | — | — | — | — | — |
| | C-1 | 1 | — | — | — | — | — | — | — |
| | C-2 | — | 1 | — | — | — | 0.3 | 15 | — |
| | C-3 | — | — | 1 | — | — | — | — | — |
| | C-4 | — | — | — | 1 | — | — | — | — |
| | C-5 | — | — | — | — | 1 | — | — | — |
| | C-6 | — | — | — | — | — | — | — | 1 |
| | C-7 | — | — | — | — | — | — | — | — |
| | C-8 | — | — | — | — | — | — | — | — |
| | C-9 | — | — | — | — | — | — | — | — |
| | C-10 | — | — | — | — | — | — | — | — |
| | C-11 | — | — | — | — | — | — | — | — |
| | C-12 | — | — | — | — | — | — | — | — |
| | C-13 | — | — | — | — | — | — | — | — |
| | C-14 | — | — | — | — | — | — | — | — |
| | C-15 | — | — | — | — | — | — | — | — |
| | C-16 | — | — | — | — | — | — | — | — |
| | C-17 | — | — | — | — | — | — | — | — |
| | C-18 | — | — | — | — | — | — | — | — |
| | C-19 | — | — | — | — | — | — | — | — |
| | C-20 | — | — | — | — | — | — | — | — |
| | CS-1 | — | — | — | — | — | — | — | — |
| | CS-2 | — | — | — | — | — | — | — | — |
| | D-1 | — | — | — | — | — | — | — | — |
| | D-2 | — | — | — | — | — | — | — | — |
| | E-1 | — | — | — | — | — | — | — | — |
| | E-2 | — | — | — | — | — | — | — | — |
| | E-3 | — | — | — | — | — | — | — | — |
| | Solvent | PGMEA | PGMEA | PGMEA | PGMEA | PGMEA | PGMEA | PGMEA | PGMEA |
| Concentration of non-volatile | | 4 | 4 | 4 | 4 | 4 | 4 | 4 | 4 |
| component (mass %) | | | | | | | | | |
| Evaluation of mold | | A | C | C | C | A | C | C | B |
| release force | | | | | | | | | |
| | | Example | | | | | | | |
| | | 9 | 10 | 11 | 12 | 13 | 14 | 15 | 16 |
| Composition | A-1 | 96 | 96 | 96 | 96 | 96 | 96 | 96 | 96 |
| | A-2 | — | — | — | — | — | — | — | — |
| | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | B-1 | 3 | 3 | 3 | 3 | 3 | 3 | 3 | 3 |
| | B-2 | — | — | — | — | — | — | — | — |
| | B-3 | — | — | — | — | — | — | — | — |
| | B-4 | — | — | — | — | — | — | — | — |
| | B-5 | — | — | — | — | — | — | — | — |
| | B-6 | — | — | — | — | — | — | — | — |
| | B-7 | — | — | — | — | — | — | — | — |
| | C-1 | — | — | — | — | — | — | — | — |
| | C-2 | — | — | — | — | — | — | — | — |
| | C-3 | — | — | — | — | — | — | — | — |
| | C-4 | — | — | — | — | — | — | — | — |
| | C-5 | — | — | — | — | — | — | — | — |
| | C-6 | — | — | — | — | — | — | — | — |
| | C-7 | 1 | — | — | — | — | — | — | — |
| | C-8 | — | 1 | — | — | — | — | — | — |
| | C-9 | — | — | 1 | — | — | — | — | — |
| | C-10 | — | — | — | 1 | — | — | — | — |
| | C-11 | — | — | — | — | 1 | — | — | — |
| | C-12 | — | — | — | — | — | 1 | — | — |
| | C-13 | — | — | — | — | — | — | 1 | — |
| | C-14 | — | — | — | — | — | — | — | 1 |
| | C-15 | — | — | — | — | — | — | — | — |
| | C-16 | — | — | — | — | — | — | — | — |
| | C-17 | — | — | — | — | — | — | — | — |
| | C-18 | — | — | — | — | — | — | — | — |
| | C-19 | — | — | — | — | — | — | — | — |
| | C-20 | — | — | — | — | — | — | — | — |
| | CS-1 | — | — | — | — | — | — | — | — |
| | CS-2 | — | — | — | — | — | — | — | — |
| | D-1 | — | — | — | — | — | — | — | — |
| | D-2 | — | — | — | — | — | — | — | — |
| | E-1 | — | — | — | — | — | — | — | — |
| | E-2 | — | — | — | — | — | — | — | — |
| | E-3 | — | — | — | — | — | — | — | — |
| | Solvent | PGMEA | PGMEA | PGMEA | PGMEA | PGMEA | PGMEA | PGMEA | PGMEA |

| | | | | | | | | |
|---|---|---|---|---|---|---|---|---|
| Concentration of non-volatile | 4 | 4 | 4 | 4 | 4 | 4 | 4 | 4 |
| component (mass %) | | | | | | | | |
| Evaluation of mold | C | C | B | C | C | C | A | C |
| release force | | | | | | | | |

TABLE 2

| | | Example | | | | | | | |
|---|---|---|---|---|---|---|---|---|---|
| | | 17 | 18 | 19 | 20 | 21 | 22 | 23 | 24 |
| Composition | A-1 | 96 | 96 | 96 | 96 | — | — | — | — |
| | A-2 | — | — | — | — | 96 | — | — | — |
| | A-3 | — | — | — | — | — | 96 | — | — |
| | A-4 | — | — | — | — | — | — | 96 | — |
| | A-5 | — | — | — | — | — | — | — | 96 |
| | A-6 | — | — | — | — | — | — | — | — |
| | B-1 | 3 | 3 | 3 | 3 | 3 | 3 | 3 | 3 |
| | B-2 | — | — | — | — | — | — | — | — |
| | B-3 | — | — | — | — | — | — | — | — |
| | B-4 | — | — | — | — | — | — | — | — |
| | B-5 | — | — | — | — | — | — | — | — |
| | B-6 | — | — | — | — | — | — | — | — |
| | B-7 | — | — | — | — | — | — | — | — |
| | C-1 | — | — | — | — | 1 | 1 | 1 | 1 |
| | C-2 | — | — | — | — | — | — | — | — |
| | C-3 | — | — | — | — | — | — | — | — |
| | C-4 | — | — | — | — | — | — | — | — |
| | C-5 | — | — | — | — | — | — | — | — |
| | C-6 | — | — | — | — | — | — | — | — |
| | C-7 | — | — | — | — | — | — | — | — |
| | C-8 | — | — | — | — | — | — | — | — |
| | C-9 | — | — | — | — | — | — | — | — |
| | C-10 | — | — | — | — | — | — | — | — |
| | C-11 | — | — | — | — | — | — | — | — |
| | C-12 | — | — | — | — | — | — | — | — |
| | C-13 | — | — | — | — | — | — | — | — |
| | C-14 | — | — | — | — | — | — | — | — |
| | C-15 | 1 | — | — | — | — | — | — | — |
| | C-16 | — | 1 | — | — | — | — | — | — |
| | C-17 | — | — | 1 | — | — | — | — | — |
| | C-18 | — | — | — | 1 | — | — | — | — |
| | C-19 | — | — | — | — | — | — | — | — |
| | C-20 | — | — | — | — | — | — | — | — |
| | CS-1 | — | — | — | — | — | — | — | — |
| | CS-2 | — | — | — | — | — | — | — | — |
| | D-1 | — | — | — | — | — | — | — | — |
| | D-2 | — | — | — | — | — | — | — | — |
| | E-1 | — | — | — | — | — | — | — | — |
| | E-2 | — | — | — | — | — | — | — | — |
| | E-3 | — | — | — | — | — | — | — | — |
| | Solvent | PGMEA | PGMEA | PGMEA | PGMEA | PGMEA | PGMEA | PGMEA | PGMEA |
| Concentration of non-volatile | | 4 | 4 | 4 | 4 | 4 | 4 | 4 | 4 |
| component (mass %) | | | | | | | | | |
| Evaluation of mold | | A | A | A | C | A | A | A | A |
| release force | | | | | | | | | |
| | | Example | | | | | | | |
| | | 25 | 26 | 27 | 28 | 29 | 30 | 31 | 32 |
| Composition | A-1 | — | 96 | 96 | 96 | 96 | 96 | 96 | 96 |
| | A-2 | — | — | — | — | — | — | — | — |
| | A-3 | — | — | — | — | — | — | — | — |
| | A-4 | — | — | — | — | — | — | — | — |
| | A-5 | — | — | — | — | — | — | — | — |
| | A-6 | 96 | — | — | — | — | — | — | — |
| | B-1 | 3 | — | — | — | — | — | — | — |
| | B-2 | — | 3 | — | — | — | — | — | — |
| | B-3 | — | — | 3 | — | — | — | — | — |
| | B-4 | — | — | — | 3 | — | — | — | — |
| | B-5 | — | — | — | — | 3 | — | — | — |
| | B-6 | — | — | — | — | — | 3 | — | — |
| | B-7 | — | — | — | — | — | — | 3 | 3 |
| | C-1 | 1 | 1 | 1 | 1 | 1 | 1 | 1 | 0.5 |
| | C-2 | — | — | — | — | — | — | — | 0.5 |
| | C-3 | — | — | — | — | — | — | — | — |
| | C-4 | — | — | — | — | — | — | — | — |
| | C-5 | — | — | — | — | — | — | — | — |
| | C-6 | — | — | — | — | — | — | — | — |
| | C-7 | — | — | — | — | — | — | — | — |
| | C-8 | — | — | — | — | — | — | — | — |
| | C-9 | — | — | — | — | — | — | — | — |
| | C-10 | — | — | — | — | — | — | — | — |
| | C-11 | — | — | — | — | — | — | — | — |
| | C-12 | — | — | — | — | — | — | — | — |
| | C-13 | — | — | — | — | — | — | — | — |
| | C-14 | — | — | — | — | — | — | — | — |
| | C-15 | — | — | — | — | — | — | — | — |
| | C-16 | — | — | — | — | — | — | — | — |
| | C-17 | — | — | — | — | — | — | — | — |
| | C-18 | — | — | — | — | — | — | — | — |
| | C-19 | — | — | — | — | — | — | — | — |
| | C-20 | — | — | — | — | — | — | — | — |
| | CS-1 | — | — | — | — | — | — | — | — |
| | CS-2 | — | — | — | — | — | — | — | — |
| | D-1 | — | — | — | — | — | — | — | — |
| | D-2 | — | — | — | — | — | — | — | — |
| | E-1 | — | — | — | — | — | — | — | — |
| | E-2 | — | — | — | — | — | — | — | — |
| | E-3 | — | — | — | — | — | — | — | — |
| | Solvent | PGMEA | PGMEA | PGMEA | PGMEA | PGMEA | PGMEA | PGMEA | PGMEA |

| | | | | | | | | |
|---|---|---|---|---|---|---|---|---|
| Concentration of non-volatile | 4 | 4 | 4 | 4 | 4 | 4 | 4 | 4 |
| component (mass %) | | | | | | | | |
| Evaluation of mold | A | A | A | C | C | B | B | B |
| release force | | | | | | | | |

TABLE 3

| | | Example | | | | | | | |
|---|---|---|---|---|---|---|---|---|---|
| | | 33 | 34 | 35 | 36 | 37 | 38 | 39 | 40 |
| Composition | A-1 | 96 | 96 | 96 | 96 | 96 | 96 | 86 | 86 |
| | A-2 | — | — | — | — | — | — | — | — |
| | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | B-1 | — | — | 3 | 3 | 3 | 3 | 3 | 3 |
| | B-2 | — | — | — | — | — | — | — | — |
| | B-3 | — | — | — | — | — | — | — | — |
| | B-4 | — | — | — | — | — | — | — | — |
| | B-5 | — | — | — | — | — | — | — | — |
| | B-6 | — | — | — | — | — | — | — | — |
| | B-7 | 3 | 3 | — | — | — | — | — | — |
| | C-1 | 0.5 | 0.5 | — | — | 0.7 | 0.7 | 1 | 1 |
| | C-2 | — | — | — | — | — | — | — | — |
| | C-3 | — | — | — | — | — | — | — | — |
| | C-4 | — | — | — | — | — | — | — | — |
| | C-5 | — | — | — | — | — | — | — | — |
| | C-6 | — | — | — | — | — | — | — | — |
| | C-7 | — | — | — | — | — | — | — | — |
| | C-8 | — | — | — | — | — | — | — | — |
| | C-9 | — | — | — | — | — | — | — | — |
| | C-10 | 0.5 | — | — | — | — | — | — | — |
| | C-11 | — | — | — | — | — | — | — | — |
| | C-12 | — | — | — | — | — | — | — | — |
| | C-13 | — | — | — | — | — | — | — | — |
| | C-14 | — | — | — | — | — | — | — | — |
| | C-15 | — | 0.5 | — | — | — | — | — | — |
| | C-16 | — | — | — | — | — | — | — | — |
| | C-17 | — | — | — | — | — | — | — | — |
| | C-18 | — | — | 1 | — | — | — | — | — |
| | C-19 | — | — | — | — | — | — | — | — |
| | C-20 | — | — | — | 1 | — | — | — | — |
| | CS-1 | — | — | — | — | — | — | — | — |
| | CS-2 | — | — | — | — | — | — | — | — |
| | D-1 | — | — | — | — | 0.3 | — | — | — |
| | D-2 | — | — | — | — | — | 0.3 | — | — |
| | E-1 | — | — | — | — | — | — | 10 | — |
| | E-2 | — | — | — | — | — | — | — | 10 |
| | E-3 | — | — | — | — | — | — | — | — |
| | Solvent | PGMEA | PGMEA | PGMEA | PGMEA | PGMEA | PGMEA | PGMEA | PGMEA |

| Concentration of non-volatile | | 4 | 4 | 4 | 4 | 4 | 4 | 4 | 4 |
|---|---|---|---|---|---|---|---|---|---|
| component (mass %) | | | | | | | | | |
| Evaluation of mold | | B | B | B | C | C | C | B | B |
| release force | | | | | | | | | |
| | | | Example | | | | | Comparative Example | |
| | | | 41 | 42 | 43 | 44 | 45 | 1 | 2 |
| | Composition | A-1 | 86 | 96 | 96 | 96 | 96 | 96 | 96 |
| | | A-2 | — | — | — | — | — | — | — |
| | | A-3 | — | — | — | — | — | — | — |
| | | A-4 | — | — | — | — | — | — | — |
| | | A-5 | — | — | — | — | — | — | — |
| | | A-6 | — | — | — | — | — | — | — |
| | | B-1 | 3 | 3 | 3 | 3 | 3 | 3 | 3 |
| | | B-2 | — | — | — | — | — | — | — |
| | | B-3 | — | — | — | — | — | — | — |
| | | B-4 | — | — | — | — | — | — | — |
| | | B-5 | — | — | — | — | — | — | — |
| | | B-6 | — | — | — | — | — | — | — |
| | | B-7 | — | — | — | — | — | — | — |
| | | C-1 | 1 | — | 1 | 1 | — | — | — |
| | | C-2 | — | — | — | — | — | — | — |
| | | C-3 | — | — | — | — | — | — | — |
| | | C-4 | — | — | — | — | — | — | — |
| | | C-5 | — | — | — | — | — | — | — |
| | | C-6 | — | — | — | — | — | — | — |
| | | C-7 | — | — | — | — | — | — | — |
| | | C-8 | — | — | — | — | — | — | — |
| | | C-9 | — | — | — | — | — | — | — |
| | | C-10 | — | — | — | — | — | — | — |
| | | C-11 | — | — | — | — | — | — | — |
| | | C-12 | — | — | — | — | — | — | — |
| | | C-13 | — | — | — | — | — | — | — |
| | | C-14 | — | — | — | — | — | — | — |
| | | C-15 | — | 0.5 | — | — | — | — | — |
| | | C-16 | — | — | — | — | — | — | — |
| | | C-17 | — | — | — | — | — | — | — |
| | | C-18 | — | — | — | — | — | — | — |
| | | C-19 | — | — | — | — | 1 | — | — |
| | | C-20 | — | — | — | — | — | — | — |
| | | CS-1 | — | 0.5 | — | — | — | 1 | — |
| | | CS-2 | — | — | — | — | — | — | 1 |
| | | D-1 | — | — | — | — | — | — | — |
| | | D-2 | — | — | — | — | — | — | — |
| | | E-1 | — | — | — | — | — | — | — |
| | | E-2 | — | — | — | — | — | — | — |
| | | E-3 | 10 | — | — | — | — | — | — |
| | | Solvent | PGMEA | PGMEA | PGMEA | PGMEA | PGMEA | PGMEA | PGMEA |

| | | | | | | | |
|---|---|---|---|---|---|---|---|
| Concentration of non-volatile | 4 | 4 | 1 | 10 | 4 | 4 | 4 |
| component (mass %) | | | | | | | |
| Evaluation of mold | B | C | A | A | B | D | D |
| release force | | | | | | | |

Details of each component in the tables are as follows.

TABLE 4

| | Name | Mw | Structural formula |
|---|---|---|---|
| A-1 | Silicone- | 2500 | Silicone-containing acrylate resin synthesized |
| | containing | | from silicone resin X-40-9225 (manufactured by |
| | acrylate | | Shin-Etsu Chemical Co., Ltd.) and 2- |
| | resin 1 | | hydroxyethyl acrylate |
| A-2 | Silicone- | 2050 | Silicone-containing acrylate resin synthesized |
| | containing | | from silicone resin KR-510 (manufactured by |
| | acrylate | | Shin-Etsu Chemical Co., Ltd.) and 2- |
| | resin 2 | | hydroxyethyl acrylate |
| A-3 | Silicone- | 2050 | Silicone-containing acrylate resin synthesized |
| | containing | | from silicone resin X-40-9225 (manufactured by |
| | acrylate | | Shin-Etsu Chemical Co., Ltd.) and 2- |
| | resin 3 | | hydroxyethyl acrylate |
| A-4 | Silicone- | 2500 | Silicone-containing acrylate resin synthesized |
| | containing | | from silicone resin X-40-9225 (manufactured by |
| | acrylate | | Shin-Etsu Chemical Co., Ltd.) and 2- |
| | resin 4 | | hydroxyethyl acrylate |
| A-5 | Silicone- | 1650 | Silicone-containing acrylate resin synthesized |
| | containing | | from silicone resin KR-5 00 (manufactured by |
| | acrylate | | Shin-Etsu Chemical Co., Ltd.) and 2- |
| | resin 5 | | hydroxyethyl acrylate |
| A-6 | Silicone- | 790 | Silicone-containing acrylate resin synthesized |
| | containing | | from silicone resin KC-89 (manufactured by |
| | acrylate | | Shin-Etsu Chemical Co., Ltd.) and 2- |
| | resin 6 | | hydroxyethyl acrylate |

### Synthesis of Silicone-Containing Acrylate Resin

A silicone resin X-40-9225 (trade name, manufactured by Shin-Etsu Chemical Co., Ltd.) (10 parts), 2-hydroxyethyl acrylate (58.1 parts), and p-toluenesulfonic acid monohydrate (0.034 parts) were mixed, then heated to 120° C., and caused to react for three hours under stirring while distilling off methanol generated by a condensation reaction to obtain 48 parts of a silicone-containing acrylate resin 1.

In addition, silicone-containing acrylate resins 2 to 6 were synthesized in the same manner as in the silicone-containing acrylate resin 1.

TABLE 5

| | Name | Structural formula |
|---|---|---|
| B-1 | Omnirad TPO H | 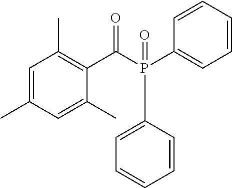 [SMILES: Cc1cc(C)c(C(=O)P(=O)(c2ccccc2)c2ccccc2)c(C)c1] |
| B-2 | Omnirad TPO-L | 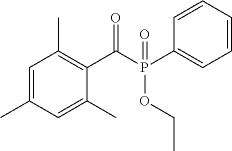 [SMILES: CCOP(=O)(C(=O)c1c(C)cc(C)cc1C)c1ccccc1] |
| B-3 | Omnirad 819 | 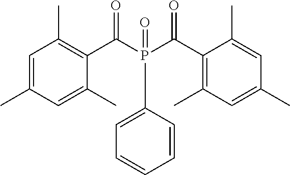 |
| B-4 | Omnirad 369 | 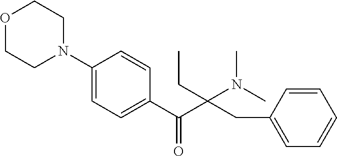 [SMILES: CCC(Cc1ccccc1)(C(=O)c1ccc(N2CCOCC2)cc1)N(C)C] |
| B-5 | Omnirad 379 | 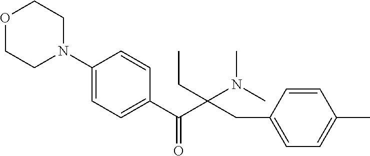 [SMILES: CCC(Cc1ccc(C)cc1)(C(=O)c1ccc(N2CCOCC2)cc1)N(C)C] |
| B-6 | Irgacure OXE01 | 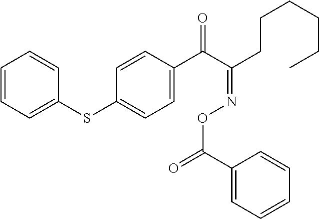 [SMILES: CCCCCC/C(=N/OC(=O)c1ccccc1)C(=O)c1ccc(Sc2ccccc2)cc1] |
| B-7 | Irgacure OXE02 | 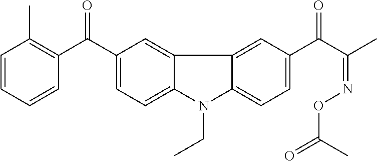 [SMILES: CCn1c2ccc(C(=O)/C(C)=N\OC(C)=O)cc2c2cc(C(=O)c3ccccc3C)ccc21] |

TABLE 6

| | Structural formula | Mw |
|---|---|---|
| C-1 | 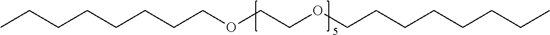 | 463 |
| C-2 | 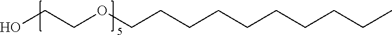 | 379 |
| C-3 | 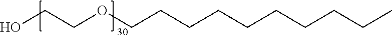 | 1480 |
| C-4 | 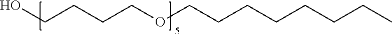 | 851 |
| C-5 | 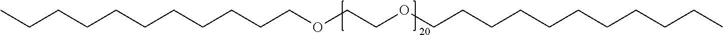 | 1208 |
| C-6 | 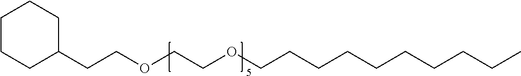 | 489 |
| C-7 | 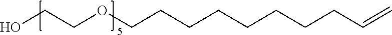 | 377 |
| C-8 | 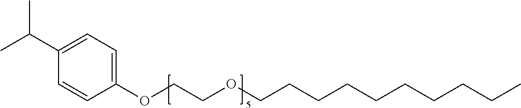 | 496 |
| C-9 | 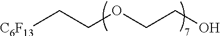 | 672 |
| C-10 | 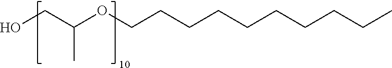 | 739 |
| C-11 | Random polymre of ethylene oxide and propylene oxide | 700 |
| | One terminal is a hydroxy group, and the other terminal is | |
| | a hexyl group. | |
| C-12 | Block polymer of ethylene oxide and propylene oxide | 700 |
| | One terminal on the ethylene oxide side is a hydroxy | |
| | group, and the other terminal is a hexyl group. | |
| C-13 | 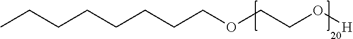 | 1011 |
| C-14 | 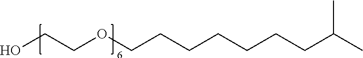 | 422.31 |
| C-15 | 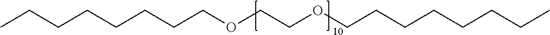 | 683 |
| C-16 | 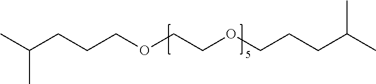 | 406.6 |

TABLE 7

| | Structural formula | Mw |
|---|---|---|
| C-17 | 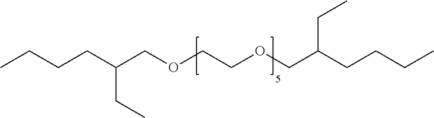 | 462.71 |
| C-18 | 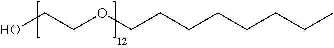 | 659 |
| C-19 | 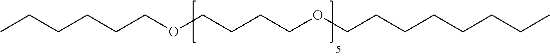 | 575 |
| C-20 | 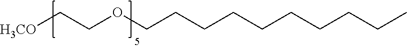 | 393 |

In the above structural formulae, the subscript of the brackets indicates the number of repetitions.

TABLE 8

| Classification | Structural formula | Mw |
|---|---|---|
| CS-1 | 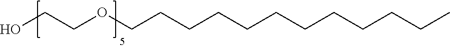 | 406.33 |
| CS-2 | 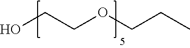 | 280.19 |

In the above structural formulae, the subscript of the brackets indicates the number of repetitions.

TABLE 9

| | Structural formula |
|---|---|
| D-1 | Stearyl acrylate |
| D-2 | FANCRYL FA-023M (Dimethacryloyl compound of polyethylene |
| | glycol-polypropylene glycol-polyethylene glycol block copolymer, |
| | manufactured by Hitachi Chemical Company, Ltd.) |

TABLE 10

| Classification | Structural formula |
|---|---|
| E-1 | 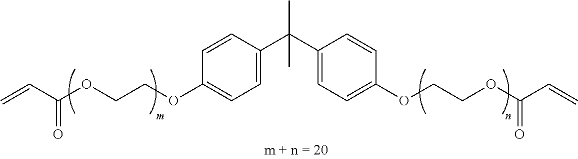 |
| E-2 | 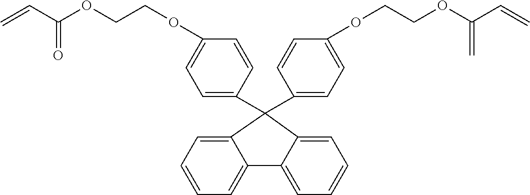 [SMILES: C=CC(=C)OCCOc1ccc(C2(c3ccc(OCCOC(=O)C=C)cc3)c3ccccc3-c3ccccc32)cc1] |
| E-3 | 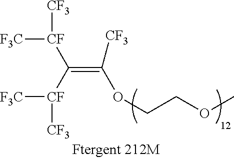 |

As can be seen from the above results, according to the curable compositions for imprinting of the present invention, cured products having a small mold release force were obtained.

In contrast, in the compositions according to Comparative Examples 1 and 2, which did not include a compound that has a monovalent hydrocarbon group having 4 to 11 carbon atoms and a poly(oxyalkylene) group, the mold release force was large.

Furthermore, an adhesive layer was formed on a silicon wafer using the composition for forming an adhesive layer by the same method as that used in the evaluation of mold releasability, and a line-and-space structure, a contact hole structure, a dual damascene structure, and a staircase structure were formed on the adhesive layer of the silicon wafer with the adhesive layer using the curable composition for imprinting according to each Example. Each silicon wafer was then dry-etched using this pattern as an etching mask, and a semiconductor element was produced using the silicon wafer. For any of the semiconductor elements, there was no problem in terms of performance. In addition, the composition for forming an adhesive layer and the curable composition for imprinting according to each Example were used to produce a semiconductor element on a substrate having a spin-on carbon (SOC) layer by the same procedure as that described above. For any of the resulting semiconductor elements, there was no problem in terms of performance.

What is claimed is:

1. A curable composition for imprinting, comprising:
an organopolysiloxane having a radical polymerizable group;
a radical generator; and
a compound that has a monovalent hydrocarbon group having 4 to 11 carbon atoms and a poly(oxyalkylene) group,
wherein some or all of hydrogen atoms of the monovalent hydrocarbon group are optionally substituted with halogen atoms.

2. The curable composition for imprinting according to claim 1, wherein the number of repetitions of an oxyalkylene group in the poly(oxyalkylene) group is 4 to 20.

3. The curable composition for imprinting according to claim 1, wherein an oxyalkylene group in the poly(oxyalkylene) group has 2 or 3 carbon atoms.

4. The curable composition for imprinting according to claim 1, wherein the monovalent hydrocarbon group is a linear alkyl group or a branched alkyl group.

5. The curable composition for imprinting according to claim 1, wherein the compound has two monovalent hydrocarbon groups, each of which is the aforementioned monovalent hydrocarbon group.

6. The curable composition for imprinting according to claim 1, wherein the monovalent hydrocarbon group is directly bonded to the poly(oxyalkylene) group.

7. The curable composition for imprinting according to claim 1, wherein the monovalent hydrocarbon group is an unsubstituted hydrocarbon group.

8. The curable composition for imprinting according to claim 1, wherein a content of the poly(oxyalkylene) group in the compound is 30% to 90% by mass.

9. The curable composition for imprinting according to claim 1, wherein the compound is a compound represented by formula (C-1) below: 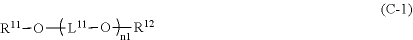
where R¹¹ and R¹² each independently represent a hydrogen atom or a monovalent organic group, at least one of R″ or R¹² is a monovalent hydrocarbon group having 4 to 11 carbon atoms, each L¹¹ independently represents an alkylene group, and n1 represents an integer of 2 or more.

10. A curable composition for imprinting, comprising:
an organopolysiloxane having a radical polymerizable group;
a radical generator; and
a compound represented by formula (C-2) below: 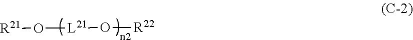
where R²¹ and R²² each independently represent a monovalent hydrocarbon group, each L²¹ independently represents an alkylene group, and n2 represents an integer of 2 or more.

11. The curable composition for imprinting according to claim 1, wherein the compound has a weight-average molecular weight of 300 to 1,000.

12. The curable composition for imprinting according to claim 1, wherein a content of the compound is 0.5% to 10% by mass relative to a total solid content of the composition.

13. The curable composition for imprinting according to claim 1, wherein the compound has no radical polymerizable group.

14. The curable composition for imprinting according to claim 1, wherein a content of the compound relative to a total mass of the organopolysiloxane is 0.5% to 10% by mass.

15. The curable composition for imprinting according to claim 1, wherein a content of a solvent relative to a total mass of the composition is 90% to 99% by mass.

16. A coating film comprising the curable composition for imprinting according to claim 1.

17. A method for producing a film, the method comprising a step of applying the curable composition for imprinting according to claim 1 onto a support or a mold.

18. A cured product obtained by curing the curable composition for imprinting according to claim 1.

19. A method for producing an imprint pattern, the method comprising:
an application step of applying the curable composition for imprinting according to claim 1 to a member to be coated selected from the group consisting of a support and a mold;
a contact step of bringing, as a contact member, a member which is not selected as the member to be coated in the group consisting of the support and the mold into contact with the curable composition for imprinting;
a curing step of curing the curable composition for imprinting to form a cured product; and
a peeling step of peeling the mold and the cured product from each other.

20. The method for producing an imprint pattern according to claim 19, wherein the support is a member comprising an adhesive layer on a surface to which the curable composition for imprinting is to be applied.

21. A method for producing a device, the method comprising the method for producing an imprint pattern according to claim 19.
